(19) United States
(12) Patent Application Publication
(10) Pub. No.: US 2017/0184971 A1
(43) Pub. Date: Jun. 29, 2017

(54) STRUCTURED ILLUMINATION OF CROSSLINKABLE POLYCARBONATE

(71) Applicant: SABIC GLOBAL TECHNOLOGIES B.V., BX Bergen op Zoom (NL)

(72) Inventor: Peter Johnson, Mount Vernon, IN (US)

(21) Appl. No.: 15/320,046

(22) PCT Filed: Jun. 19, 2015
(86) PCT No.: PCT/IB2015/054647

§ 371 Date: Dec. 19, 2016

Related U.S. Application Data
(60) Provisional application No. 62/014,845, filed on Jun. 20, 2014.

(51) Int. Cl. G03F 7/20; G03F 7/039; C08G 64/40; G03F 7/038

(52) U.S. Cl. CPC G03F 7/2002; G03F 7/038; G03F 7/039; C08G 64/40

(57) ABSTRACT

Methods and systems for photopatterning a polycarbonate article are described. The article comprises a cross-linkable polycarbonate with a photoactive group derived from a benzophenone. The article is selectively exposed to UV radiation to cause crosslinking at exposed portions of the article. This can be done by using a photomask to shield portions that are not to be cross-linked, or by focusing light on selective portions of the article. Systems for practicing the methods include a polycarbonate article, a UV light source, and a photomask including a plurality of openings for selectively exposing the polycarbonate article to UV light.

### CROSS-REFERENCE TO RELATED APPLICATIONS

This application claims priority to U.S. Provisional Patent Application Ser. No. 62/014,845, filed on Jun. 20, 2014, which is fully incorporated by reference herein.

### BACKGROUND

The present disclosure relates to methods and systems for structured illumination and photopatterning of a polycarbonate article. The article includes a cross-linkable polycarbonate resin containing a photoactive group derived from a benzophenone. The article is selectively exposed to UV radiation. In those portions thus exposed, the cross-linkable polycarbonate resin will crosslink with itself and/or with other polymeric base resins also present, improving overall chemical resistance and flame retardance and other mechanical properties. Also included are the articles (e.g., molded articles, sheets, films, molded components, etc.) formed thereby.

Polycarbonates (PC) are thermoplastic resins with desirable properties such as high impact strength and toughness, transparency, and heat resistance. However, they also drip when exposed to a flame, and this behavior worsens as wall thickness decreases. This is undesirable for applications requiring V0 or 5VA performance. It would be desirable to provide articles and polymeric compositions that have good flame resistance, good chemical resistance, and good aesthetic effects.

### BRIEF DESCRIPTION

The present disclosure relates to structured illumination of polycarbonate articles that permits control over cross-linking activity on the article and the refractive index of the article. A photomask can be used to permit UV exposure in some locations/regions of an article and to block UV exposure in other locations/regions. The resulting article has some cross-linked regions and some non-cross-linked regions on the surface of the article.

Disclosed in various embodiments herein are methods of photopatterning a polycarbonate article, comprising: receiving an article formed from a polymeric composition comprising a cross-linkable polycarbonate resin containing a photoactive group derived from a benzophenone; and selectively exposing a portion of the article to an effective dosage of ultraviolet radiation to cause cross-linking of the polycarbonate resin at the portion of the article and create a pattern on the article.

The portion of the article can be selectively exposed by using a photomask to shield other portions of the article from exposure to the ultraviolet radiation. Alternatively, the portion of the article can be selectively exposed by focusing an ultraviolet light source at the selectively exposed portion. The selectively exposed portion of the article may be a potential failure point, a knit line, or an edge, where increased dimensional stability is desired. The portion of the article may be selectively exposed by a photomask pattern having a smallest resolution from 0.075 milliliter (mm) to 10.0 mm to form a cross-linked portion.

The effective dosage may be from about 6 Joules per square centimeter (J/cm²) to about 36 J/cm² of UVA radiation. The ultraviolet radiation may have a wavelength between 280 nanometer (nm) and 380 nm. The ultraviolet radiation may be provided by a collimated UV light source.

The benzophenone from which the photoactive group is derived may be a monohydroxybenzophenone. In such embodiments, the cross-linkable polycarbonate resin can be formed from a reaction comprising: the monohydroxybenzophenone; a diol chain extender; and a first linker moiety comprising a plurality of linking groups, wherein each linking group can react with the hydroxyl groups of the monohydroxybenzophenone and the diol chain extender. The cross-linkable polycarbonate resin may contain from about 0.5 mole % to about 5 mole % of endcap groups derived from the monohydroxybenzophenone.

In other embodiments, the benzophenone from which the photoactive group is derived may be a dihydroxybenzophenone. In such embodiments, the cross-linkable polycarbonate resin can be formed from a reaction comprising: the dihydroxybenzophenone; a diol chain extender; a first linker moiety comprising a plurality of linking groups, wherein each linking group can react with the hydroxyl groups of the dihydroxybenzophenone and the diol chain extender; and an endcapping agent. In specific embodiments, the dihydroxybenzophenone is 4,4′-dihydroxybenzophenone; the diol chain extender is bisphenol-A; and the first linker moiety is phosgene. The end-capping agent can be selected from the group consisting of phenol, p-t-butylphenol, p-cumylphenol, octylphenol, and p-cyanophenol. The cross-linkable polycarbonate resin may contain from about 0.5 mole % to about 50 mole % of repeating units derived from the dihydroxybenzophenone.

In particular embodiments, the composition further comprises a polymeric base resin (i.e. a blend). The weight ratio of the cross-linkable polycarbonate resin to the polymeric base resin can be from about 50:50 to about 85:15.

Also disclosed are the polycarbonate articles formed thereby. The article may be a molded article, a film, a sheet, a layer of a multilayer film, or a layer of a multilayer sheet.

These and other non-limiting characteristics are more particularly described below.

### BRIEF DESCRIPTION OF THE DRAWINGS

The following drawings are presented to illustrate the exemplary embodiments disclosed herein and not to limit them.

FIG. 1 illustrates the formation of a cross-linkable polycarbonate resin (oligomer/polymer) from a dihydroxybenzophenone (4,4′-dihydroxybenzophenone), a first linker moiety (phosgene), a diol chain extender (bisphenol-A), and an end-capping agent (p-cumylphenol).

FIG. 2 illustrates the formation of a branched cross-linkable polycarbonate (oligomer/polymer) from a dihydroxybenzophenone (4,4′-dihydroxybenzophenone), a first linker moiety (phosgene), a diol chain extender (bisphenol-A), an end-capping agent (p-cumylphenol), and a secondary linker moiety (1,1,1-tris-hydroxyphenylethane (THPE)).

FIG. 3 illustrates the formation of a cross-linkable polycarbonate (oligomer/polymer) from a monohydroxybenzophenone (4-hydroxybenzophenone), a first linker moiety (phosgene), and a diol chain extender (bisphenol-A).

FIG. 4 illustrates the formation of a cross-linkable polycarbonate (oligomer/polymer) from a monohydroxybenzophenone (4-hydroxybenzophenone), a first linker moiety (phosgene), a diol chain extender (bisphenol-A), and an additional endcapping agent (p-cumylphenol).

FIG. 5 illustrates the crosslinking mechanism of the cross-linkable polycarbonate.

FIG. 6A is a photograph of a photomask with a holed pattern used for a photopattern study. The openings of the photomask have a diameter of 250 micrometers (μm), with 750 μm spacing between the centers of the holes. The holes are arranged in a hexagonal design.

FIG. 6B is a photograph of a different photomask with a different holed pattern used for a photopattern study. The openings of the photomask have a diameter of 75 μm, with 930 μm spacing between the centers of the holes. The holes are arranged in a hexagonal design.

FIG. 7A is a photograph of the replication produced by exposing a cross-linkable HBP polycarbonate film covered by the photomask of FIG. 6A to 36 J/cm² of UVA light. The replication is viewed under non-polarized light.

FIG. 7B is a photograph of the replication produced by exposing a cross-linkable HBP polycarbonate film covered by the photomask of FIG. 6B to 36 J/cm² of UVA light. The replication is viewed under non-polarized light.

FIG. 8A is a photograph of the replication produced by exposing a cross-linkable DHBP polycarbonate film covered by the photomask of FIG. 6A to 36 J/cm² of UVA light. The replication is viewed under non-polarized light.

FIG. 8B is a photograph of the replication produced by exposing a cross-linkable DHBP polycarbonate film covered by the photomask of FIG. 6B to 36 J/cm² of UVA light. The replication is viewed under non-polarized light.

### DETAILED DESCRIPTION

In the following specification, the examples, and the claims which follow, reference will be made to some terms which are defined as follows.

### Definitions

Unless otherwise defined, all technical and scientific terms used herein have the same meaning as commonly understood by one of ordinary skill in the art. In case of conflict, the present document, including definitions, will control. All publications, patent applications, patents and other references mentioned herein are incorporated by reference in their entirety.

The singular forms “a,” “an,” and “the” include plural referents unless the context clearly dictates otherwise.

As used in the specification and in the claims, the open-ended transitional phrases “comprise(s),” “include(s),” “having,” “contain(s),” and variants thereof require the presence of the named ingredients/steps and permit the presence of other ingredients/steps. These phrases should also be construed as disclosing the closed-ended phrases “consist of” or “consist essentially of” that permit only the named ingredients/steps and unavoidable impurities, and exclude other ingredients/steps.

Numerical values used herein should be understood to include numerical values which are the same when reduced to the same number of significant figures and numerical values which differ from the stated value by less than the experimental error of the measurement technique described for determining the value.

All ranges disclosed herein are inclusive of the recited endpoint and independently combinable (for example, the range of “from 2 grams to 10 grams” is inclusive of the endpoints, 2 grams and 10 grams, and all the intermediate values).

The term “about” can be used to include any numerical value that can carry without changing the basic function of that value. When used with a range, “about” also discloses the range defined by the absolute values of the two endpoints, e.g., “about 2 to about 4” also discloses the range “from 2 to 4.” The term “about” may refer to plus or minus 10% of the indicated number.

Compounds are described using standard nomenclature. Any position not substituted by an indicated group is understood to have its valency filled by a bond or a hydrogen atom. A dash (“-”) that is not between two letters indicates a point of attachment for a substituent, e.g. —CHO attaches through the carbon atom.

The term “aliphatic” refers to an array of atoms that is not aromatic. The backbone of an aliphatic group is composed exclusively of carbon. An aliphatic group is substituted or unsubstituted. Exemplary aliphatic groups are ethyl and isopropyl.

An “aromatic” radical has a ring system containing a delocalized conjugated pi system with a number of pi-electrons that obeys Hückel's Rule. The ring system may include heteroatoms (e.g. N, S, Se, Si, O), or may be composed exclusively of carbon and hydrogen. Aromatic groups are not substituted. Exemplary aromatic groups include phenyl, thienyl, naphthyl, and biphenyl.

An “ester” radical has the formula —CO—O—, with the carbon atom and the oxygen atom both bonded to carbon atoms. A “carbonate” radical has the formula —O—CO—O—, with the oxygen atoms both bonded to carbon atoms. Note that a carbonate group is not an ester group, and an ester group is not a carbonate group.

A “hydroxyl” radical has the formula —OH, with the oxygen atom bonded to a carbon atom. A “carboxy” or “carboxyl” radical has the formula —COOH, with the carbon atom bonded to another carbon atom. A carboxyl group can be considered as having a hydroxyl group. However, please note that a carboxyl group participates in certain reactions differently from a hydroxyl group. An “anhydride” radical has the formula —CO—O—CO—, with the carbonyl carbon atoms bonded to other carbon atoms. This radical can be considered equivalent to two carboxyl groups. The term “acid halide” refers to a radical of the formula —CO—X, with the carbon atom bonded to another carbon atom.

The term “alkyl” refers to a fully saturated radical composed entirely of carbon atoms and hydrogen atoms. The alkyl radical may be linear, branched, or cyclic. The term “aryl” refers to an aromatic radical composed exclusively of carbon and hydrogen. Exemplary aryl groups include phenyl, naphthyl, and biphenyl. The term “hydrocarbon” refers to a radical which is composed exclusively of carbon and hydrogen. Both alkyl and aryl groups are considered hydrocarbon groups. The term “heteroaryl” refers to an aromatic radical containing at least one heteroatom. Note that “heteroaryl” is a subset of aromatic, and is exclusive of “aryl”.

The term “halogen” refers to fluorine, chlorine, bromine, and iodine. The term “halo” means that the substituent to which the prefix is attached is substituted with one or more independently selected halogen radicals.

The term “alkoxy” refers to an alkyl radical which is attached to an oxygen atom, i.e. —O—CₙH₂ₙ₊₁. The term “aryloxy” refers to an aryl radical which is attached to an oxygen atom, e.g. —O—C₆H₅.

An “alkenyl” radical is composed entirely of carbon atoms and hydrogen atoms and contains a carbon-carbon double bond that is not part of an aromatic structure. An exemplary alkenyl radical is vinyl (—CH═CH₂).

The term “alkenyloxy” refers to an alkenyl radical which is attached to an oxygen atom, e.g. —O—CH═CH₂. The term “arylalkyl” refers to an aryl radical which is attached to an alkyl radical, e.g. benzyl (—CH₂—C₆H₅). The term “alkylaryl” refers to an alkyl radical which is attached to an aryl radical, e.g. tolyl (—C₆H₄—CH₃).

The term “substituted” refers to at least one hydrogen atom on the named radical being substituted with another functional group, such as halogen, —CN, or —NO₂. However, the functional group is not hydroxyl, carboxyl, ester, acid halide, or anhydride. Besides the aforementioned functional groups, an aryl group may also be substituted with alkyl or alkoxy. An exemplary substituted aryl group is methylphenyl.

The term “copolymer” refers to a molecule derived from two or more structural unit or monomeric species, as opposed to a homopolymer, which is a molecule derived from only one structural unit or monomer.

The terms “Glass Transition Temperature” or “Tg” refer to the maximum temperature that a polycarbonate will retain at least one useful property such as impact resistance, stiffness, strength, or shape retention. The Tg can be determined by differential scanning calorimetry.

The term “haze” refers to the percentage of transmitted light, which in passing through a specimen deviates from the incident beam by forward scattering. Percent (%) haze may be measured according to ASTM D1003-13.

The term “Melt Volume Rate” (MVR) or “Melt Flow Rate (MFR)” refers to the flow rate of a polymer in a melt phase as determined using the method of ASTM D1238-13. MVR is expressed in cubic centimeter per 10 minutes, and MFR is expressed in grams per 10 minutes. The higher the MVR or MFR value of a polymer at a specific temperature, the greater the flow of that polymer at that specific temperature.

The term “percent light transmission” or “% T” refers to the ratio of transmitted light to incident light, and may be measured according to ASTM D1003-13.

“Polycarbonate” as used herein refers to an oligomer or a polymer comprising residues of one or more monomers, joined by carbonate linkages.

The terms “UVA”, “UVB”, “UVC”, and “UVV” as used herein were defined by the wavelengths of light measured with the radiometer (EIT PowerPuck) used in these studies, as defined by the manufacturer (EIT Inc., Sterling, Va.). “UV” radiation refers to wavelengths of 200 nm to 450 nm. UVA refers to the range from 320-390 nm, UVB to the range from 280-320 nm, UVC to the range from 250-260 nm, and UVV to the range from 395-445 nm.

The term “crosslink” and its variants refer to the formation of a stable covalent bond between two polymers/oligomers. This term is intended to encompass the formation of covalent bonds that result in network formation, or the formation of covalent bonds that result in chain extension. The term “cross-linkable” refers to the ability of a polymer/oligomer to initiate the formation of such stable covalent bonds.

The present disclosure refers to “polymers,” “oligomers”, and “compounds”. A polymer is a large molecule composed of multiple repeating units chained together. Different molecules of a polymer will have different lengths, and so a polymer has a molecular weight that is based on the average value of the molecules (e.g. weight average or number average molecular weight). An “oligomer” has only a few repeating units, while a “polymer” has many repeating units. In this disclosure, “oligomer” refers to molecules having a weight average molecular weight (Mw) of less than 15,000, and the term “polymer” refers to molecules having an Mw of 15,000 or more, as measured by GPC using polycarbonate molecular weight standards, measured prior to any UV exposure. In a compound, all molecules have the same molecular weight. Molecular weights are reported herein in Daltons or g/mol.

A “photomask” is a patterned substrate that blocks some light while selectively permitting other light to pass. Patterns may contain a combination of opaque, partially opaque, or transparent regions. The pattern designs are contemplated as containing any number of features such as openings, dots, lines, or figures of different sizes and dimensions which are combined to create the appropriate pattern.

Articles

The present disclosure relates to polycarbonate articles made from a polymeric composition comprising a cross-linkable polycarbonate resin having a photoactive group derived from a benzophenone. The polycarbonates are selectively exposed to UV light. In the portions/regions that are exposed to UV light, crosslinking occurs. This can be used to improve the chemical resistance, flame performance, and other mechanical properties of portions of the article which might be abused more than other non-exposed portions. Alternatively, the UV exposure can be used to control the overall refractive index of the article.

Generally, the photoactive additives (PAA) of the present disclosure are cross-linkable polycarbonate resins that contain photoactive ketone groups. The term “photoactive” refers to a moiety that, when exposed to ultraviolet light of the appropriate wavelength, crosslinks with another molecule. For example, the bisphenol-A monomer in a bisphenol-A homopolycarbonate is not considered to be photoactive, even though photo-Fries rearrangement can occur, because the atoms do not crosslink, but merely rearrange in the polymer backbone. A “ketone group” is a carbonyl group (—CO—) that is bonded to two other carbon atoms (i.e. —R—CO—R′—). An ester group and a carboxylic acid group are not a ketone group because their carbonyl group is bonded to an oxygen atom.

The photoactive additive is formed from a reaction mixture containing at least a benzophenone and a first linker moiety. The benzophenone has either one or two phenolic groups, and provides a photoactive ketone group for crosslinking. The first linker moiety comprises a plurality of functional groups that can react with the phenolic group(s) of the benzophenone. The reaction product of this mixture is the photoactive additive. Depending on whether the benzophenone is monofunctional or difunctional, an end-capping agent may also be included. As desired, a diol chain extender can also be included. The end-capping agent and the diol chain extender do not have photoactive properties.

In some embodiments, the benzophenone is a monohydroxybenzophenone, and has the structure of Formula (I):

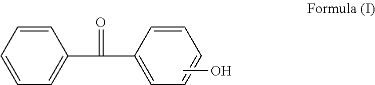

In more specific embodiments, the monohydroxybenzophenone is 4-hydroxybenzophenone (4-HBP).

In other embodiments, the benzophenone is a dihydroxybenzophenone, and has the structure of Formula (II):

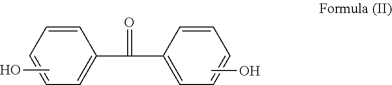

The two hydroxyl groups can be located in any combination of locations, e.g. 4,4′-; 2,2′-; 2,4′-; etc. In more specific embodiments, the dihydroxybenzophenone is 4,4′-dihydroxybenzophenone (4,4′-DHBP).

The photoactive hydroxybenzophenone is reacted with one or more first linker moieties. At least one of the first linker moieties comprises a plurality of functional groups that can react with the phenolic group of the photoactive benzophenones. Examples of such functional groups include a carboxylic acid (and anhydrides thereof), an acyl halide, an alkyl ester, and an aryl ester. These functional groups have the general formula —COY, wherein Y is hydroxyl, halogen, alkoxy, or aryloxy. The functional groups can be joined to an aliphatic group or an aromatic group which serves as a “backbone” for the linker moiety. In particular embodiments, the first linker moiety can have two, three, four, or even more functional groups. As a result, depending on its identity and on the other ingredients in the reaction, the first linker moiety can act as a branching agent.

Some examples of first linker moieties which have two functional groups and can react with the photoactive hydroxybenzophenones include those having the structure of one of formulas (1)-(4):

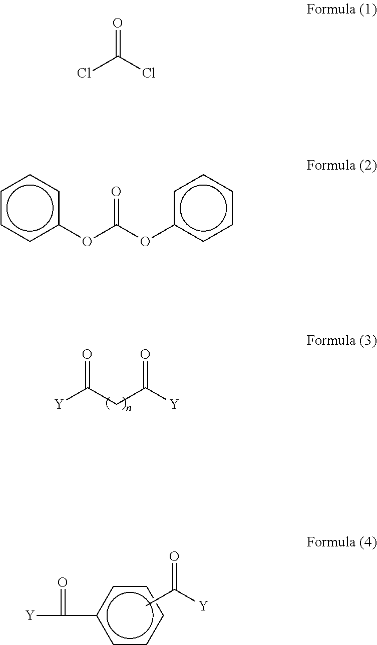

where Y is hydroxyl, halogen, alkoxy, or aryloxy; and where n is 1 to 20. It should be noted that Formula (3) encompasses adipic acid (n=4), sebacic acid (n=8), and dodecanedioic acid (n=10). Similarly, Formula (4) encompasses isophthalic acid and terephthalic acid. When diacids are used, the crosslinkable polycarbonate of the present disclosure may be a polyester-polycarbonate. The molar ratio of ester units to carbonate units in the polyester-polycarbonate may be 1:99 to 99:1, specifically 10:90 to 90:10, or 25:75 to 75:25.

Some examples of first linker moieties which have three functional groups and can react with the photoactive hydroxybenzophenones include those having the structure of one of the Formulas (5)-(7):

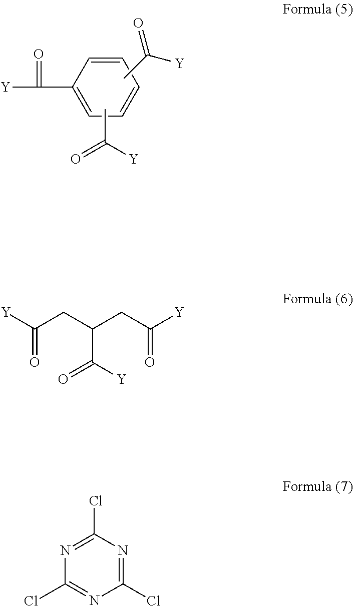

where Y is hydroxyl, halogen, alkoxy, or aryloxy.

Some examples of first linker moieties which have four functional groups and can react with the photoactive hydroxybenzophenones include those having the structure of one of Formulas (8)-(10):

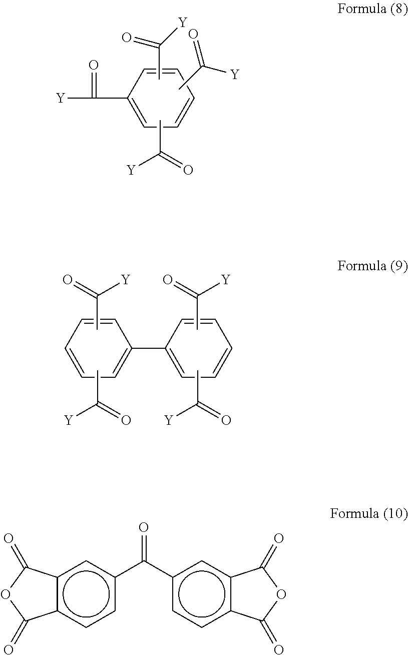

where Y is hydroxyl, halogen, alkoxy, or aryloxy.

In some embodiments, functional groups can be provided by short oligomers, including oligomers containing glycidyl methacrylate monomers with styrene or methacrylate monomers, or epoxidized novolac resins. These oligomers can permit the desired number of functional groups to be provided. Such oligomers are generalized by the structure of Formula (11):

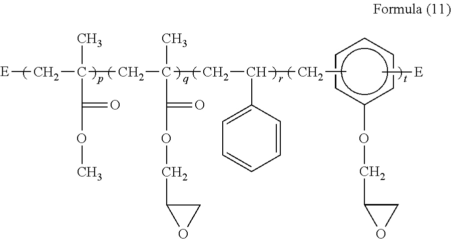

where E is hydrogen or an end-capping agent, p is the number of methacrylate monomers, q is the number of methacrylate monomers, r is the number of styrene monomers, and t is the number of epoxidized novolac (phenol-formaldehyde) monomers. Generally p+q+r+t≦20. When the oligomer contains glycidyl methacrylate monomers with styrene or methacrylate monomers, generally t=0 and q≧1. Similarly, for novolac resins, p=q=r=0. The epoxy groups can be reacted with the phenolic group of the photoactive benzophenone.

It is noted that using phosgene and diphenyl carbonate, Formulas (1) and (2) respectively, will result in the formation of carbonate linkages, while using the other first linker moieties will generally result in the formation of ester linkages. In particular embodiments, phosgene or diphenyl carbonate is used as the first linker moiety.

When the benzophenone is a monohydroxybenzophenone, the molar ratio of the benzophenone to the first linker moiety can be from 1:2 to 1:200 prior to UV exposure, including from about 1:10 to about 1:200 or from about 1:20 to about 1:200. When the benzophenone is a dihydroxybenzophenone, the molar ratio of the benzophenone to the first linker moiety can be from 1:1 to 1:200 prior to UV exposure, including from 1:2 to 1:200, or from about 1:99 to about 3:97, or from about 1:99 to about 6:94, or from about 10:90 to about 25:75 or from about 1:3 to about 1:200.

In particularly desired embodiments, the photoactive additive can be formed from a reaction mixture containing the photoactive benzophenone, the first linker moiety, and one or more diol chain extenders. The diol chain extender is a molecule that contains only two hydroxyl groups and is not photoactive when exposed to light. The chain extender can be used to provide a desired level of miscibility. The photoactive additive may comprise from about 75 mole % to about 99.5 mole %, or from 95 mole % to about 99 mole %, or from about 80 mole % to about 95 mole %, or from about 80 mole % to about 90 mole %, of the diol chain extender.

A first exemplary diol chain extender is a bisphenol of Formula (A):

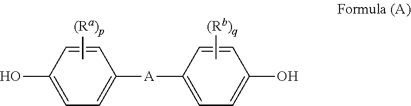

wherein R^{a} and R^{b} each represent a halogen atom or a monovalent hydrocarbon group and may be the same or different; p and q are each independently integers of 0 to 4; and A represents one of the groups of Formula (A-1):

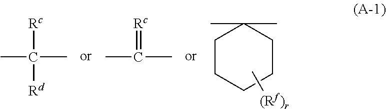

wherein R^{c} and R^{d} each independently represent a hydrogen atom or a monovalent linear or cyclic hydrocarbon group; R^{e} is a divalent hydrocarbon group; R^{f} is a monovalent linear hydrocarbon group; and r is an integer from 0 to 5. For example, A can be a substituted or unsubstituted C₃-C₁₈ cycloalkylidene.

Specific examples of the types of bisphenol compounds that may be represented by Formula (A) include 2,2-bis(4-hydroxyphenyl) propane (“bisphenol-A” or “BPA”), 4,4′-(1-phenylethane-1,1-diyl)diphenol or 1,1-bis(4-hydroxyphenyl)-1-phenylethane (bisphenol-AP); 1,1-bis(4-hydroxyphenyl)-3,3,5-trimethylcyclohexane) (bisphenol TMC); 1,1-bis(4-hydroxy-3-methylphenyl) cyclohexane (DMBPC); and 2,2-bis(3,5-dibromo-4-hydroxyphenyl) propane (tetrabromobisphenol-A or TBBPA).

A second exemplary diol chain extender is a bisphenol of Formula (B):

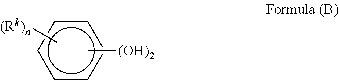

wherein each R^{k} is independently a C₁₋₁₀ hydrocarbon group, and n is 0 to 4. The halogen is usually bromine. Examples of compounds that may be represented by Formula (B) include resorcinol, 5-methyl resorcinol, 5-phenyl resorcinol, catechol; hydroquinone; and substituted hydroquinones such as 2-methyl hydroquinone.

A third exemplary diol chain extender is a bisphenolpolydiorganosiloxane of Formula (C-1) or (C-2):

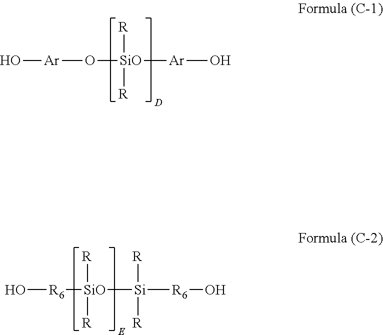

wherein each Ar is independently aryl; each R is independently alkyl, alkoxy, alkenyl, alkenyloxy, aryl, aryloxy, arylalkyl, or alkylaryl; each R₆ is independently a divalent C₁-C₃₀ organic group such as a C₁-C₃₀ alkyl, C₁-C₃₀ aryl, or C₁-C₃₀ alkylaryl; and D and E are an average value of 2 to about 1000, including from about 2 to about 500, or about 10 to about 200, or more specifically about 10 to about 75.

Specific examples of Formulas (C-1) and (C-2) are illustrated below as Formulas (C-a) through (C-d):

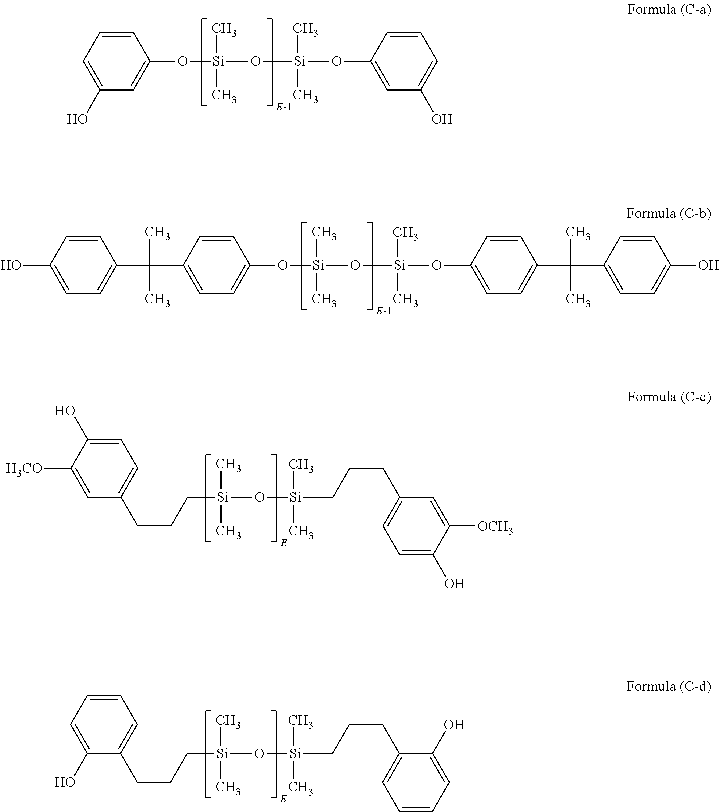

where E is an average value from 10 to 200.

A fourth exemplary diol chain extender is an aliphatic diol of Formula (D):

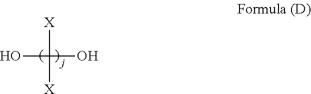

wherein each X is independently hydrogen, halogen, or alkyl; and j is an integer from 1 to 20. Examples of an aliphatic diol include ethylene glycol, propanediol, 2,2-dimethyl-propanediol, 1,6-hexanediol, and 1,12-dodecanediol.

A fifth exemplary diol chain extender is a dihydroxy compound of Formula (E), which may be useful for high heat applications:

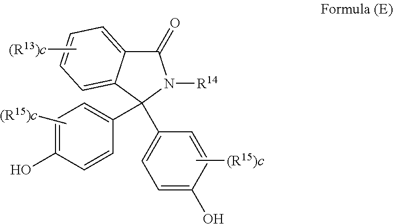

wherein R¹³ and R¹⁵ are each independently halogen or C₁-C₆ alkyl, R¹⁴ is C₁-C₆ alkyl, or phenyl substituted with up to five halogens or C₁-C₆ alkyl groups, and c is 0 to 4. In specific embodiments, R¹⁴ is a C₁-C₆ alkyl or phenyl group; or each c is 0. Compounds of Formula (E) include 3,3-bis(4-hydroxyphenyl)-2-phenylisoindolin-1-one (PPPBP).

Another dihydroxy chain extender that might impart high Tgs to the polycarbonate has adamantane units. Such compounds may have repetitive units of the following formula (F) for high heat applications:

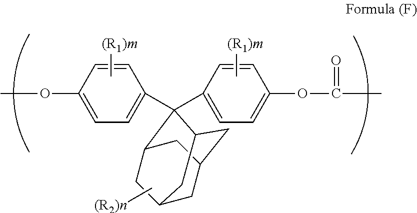

wherein R₁ is halogen, C₁-C₆ alkyl, C₁-C₆ alkoxy, C₆-C₁₂ aryl, C₇-C₁₃ aryl-substituted alkenyl, or C₁-C₆ fluoroalkyl; R₂ is halogen, C₁-C₁₂ alkyl, C₁-C₁₂ alkoxy, C₆-C₁₂ aryl, C₇-C₁₃ aryl-substituted alkenyl, or C₁-C₁₂ fluoroalkyl; m is an integer of 0 to 4; and n is an integer of 0 to 14.

Another dihydroxy compound that might impart high Tgs to the polycarbonate is a fluorene-unit containing dihydroxy compound represented by the following Formula (G):

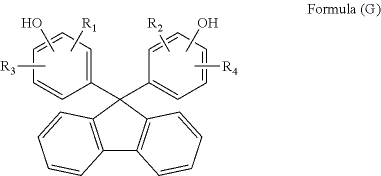

wherein R₁ to R₄ are each independently hydrogen, C₁-C₉ hydrocarbon, or halogen.

Another diol chain extender that could be used is an isosorbide. A monomer unit derived from isosorbide may be an isorbide-bisphenol unit of Formula (H):

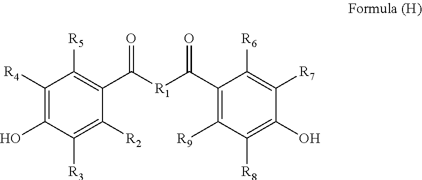

wherein R₁ is an isosorbide unit and R₂-R₉ are each independently a hydrogen, a halogen, a C₁-C₆ alkyl, a methoxy, an ethoxy, or an alkyl ester.

The R₁ isosorbide unit may be represented by Formula (H-a):

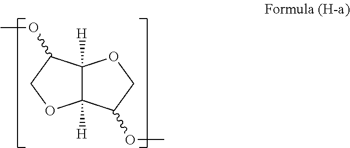

The isosorbide unit may be derived from one isosorbide, or be a mixture of isomers of isosorbide. The stereochemistry of Formula (I) is not particularly limited. These diols may be prepared by the dehydration of the corresponding hexitols. The isosorbide-bisphenol may have a pKa of between 8 and 11.

As previously explained, a photoactive hydroxybenzophenone is reacted with a first linker moiety to obtain the photoactive additive. In some embodiments, a secondary linker moiety is included in the reaction mixture. The secondary linker moiety has at least three functional groups, each of which can react with the functional groups of the first linker moiety, and acts as a branching agent. Generally, the functional groups of the secondary linker moiety are hydroxyl groups.

Some examples of secondary linker moieties which have three functional groups and can react with the first linker moiety include 1,1,1-trimethoxyethane; 1,1,1-trimethoxymethane; 1,1,1-tris (hydroxyphenyl) ethane (THPE), and 1,3,5-tris[2-(4-hydroxyphenyl)-propan-2-yl]benzene. Some examples of secondary linker moieties which have four functional groups and can react with the first linker moiety include pentaerythritol and 4-[2,6,6-tris(4-hydroxyphenyl)heptan-2-yl]phenol. In other embodiments, the secondary linker moiety can be an oligomer, made from epoxidized novolac monomer, that permits the desired number of functional groups to be provided.

An end-capping agent is generally used to terminate any polymer chains of the photoactive additive. The end-capping agent (i.e. chain stopper) can be a monohydroxy compound, a mono-acid compound, or a mono-ester compound. Exemplary endcapping agents include phenol, p-cumylphenol (PCP), resorcinol monobenzoate, p-tert-butylphenol, octylphenol, p-cyanophenol, and p-methoxyphenol. Unless modified with other adjectives, the term “end-capping agent” is used herein to denote a compound that is not photoactive when exposed to light. For example, the end-capping agent does not contain a ketone group. The photoactive additive may comprise about 0.5 mole % to about 5.0 mole % endcap groups derived from this non-photoactive. It is noted that when the photoactive hydroxybenzophenone is a monohydroxybenzophenone, the monohydroxybenzophenone acts as an end-capping agent. In that situation, a second end-capping agent can also be used. The photoactive additive may comprise about 0.5 mole % to about 5.0 mole % endcap groups derived from each end-capping agent, including about 1 mole % to about 3 mole %, or from about 1.7 mole % to about 2.5 mole %, or from about 2 mole % to about 2.5 mole %, or from about 2.5 mole % to about 3.0 mole % endcap groups derived from each end-capping agent.

The photoactive additives of the present disclosure have photoactive groups that are derived from either a monohydroxybenzophenone or a dihydroxybenzophenone. When a monohydroxybenzophenone is used, the reaction mixture generally also includes a diol chain extender and a first linker moiety. The diol chain extender provides a monomer, and the monohydroxybenzophenone acts as an endcapping agent. The resulting additive can be considered a homopolymer. If desired, a secondary linker moiety can also be used. When a dihydroxybenzophenone is used, the reaction mixture generally also includes the first linker moiety, an endcapping agent, and a diol chain extender. The resulting additive can be considered a copolymer with the dihydroxybenzophenone and the diol chain extender acting as monomers.

The photoactive additives of the present disclosure can be a compound, an oligomer, or a polymer. The oligomer has a weight average molecular weight (Mw) of less than 15,000, including 10,000 or less. The polymeric photoactive additives of the present disclosure have a Mw of 15,000 or higher. In particular embodiments, the Mw is between 17,000 and 80,000 Daltons, or between 17,000 and 35,000 Daltons. These molecular weights are measured prior to any UV exposure. The Mw may be varied as desired. In some particular embodiments, the Mw of the photoactive additives is about 5,000 or less.

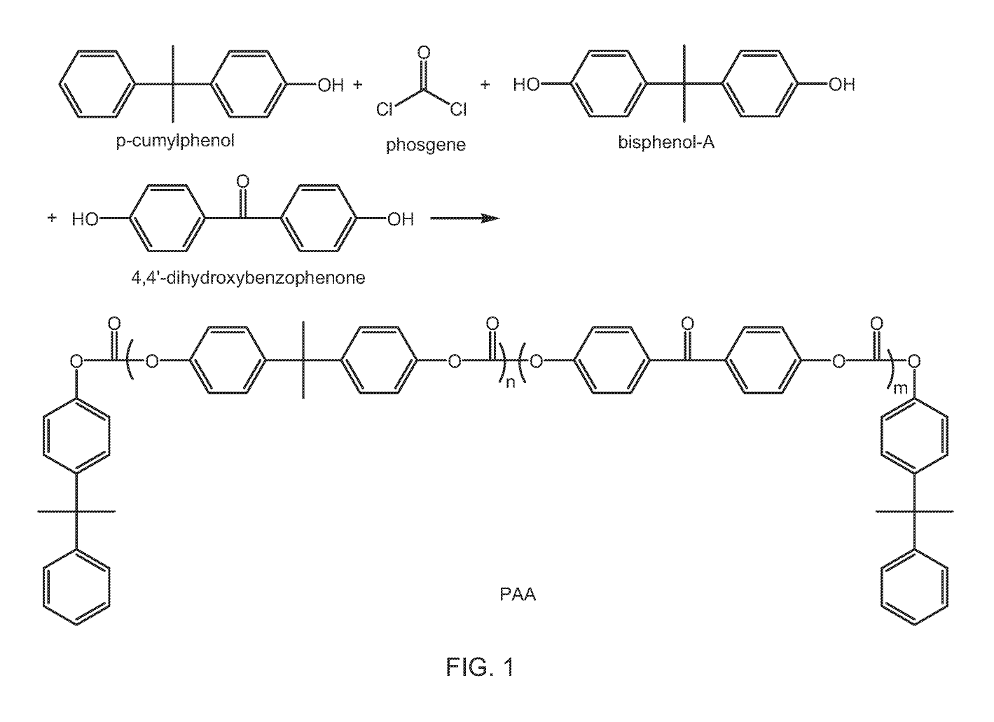

One example of a photoactive additive is a cross-linkable polycarbonate resin shown in FIG. 1. Here, 4,4′-dihydroxybenzophenone is reacted with phosgene (first linker moiety), bisphenol-A (diol chain extender), and p-cumylphenol (end-capping agent) to obtain the cross-linkable polycarbonate resin. A copolymer is thus formed with a weight average molecular weight and a polydispersity index, and containing carbonate linkages.

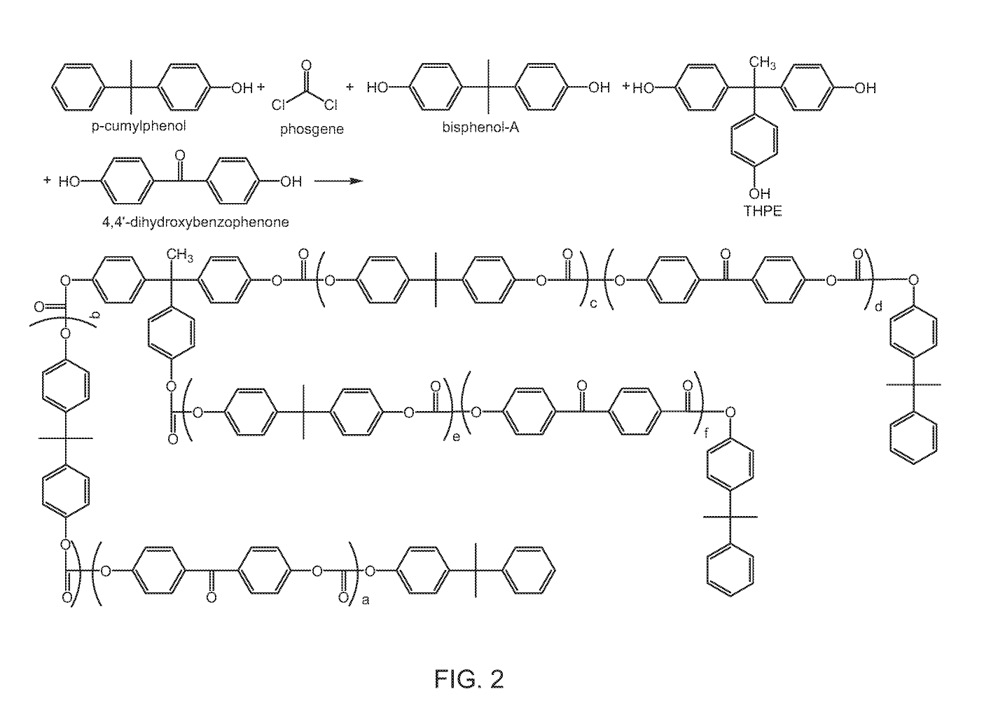

FIG. 2 illustrates the formation of a branched cross-linkable polycarbonate. As illustrated here, 4,4′-dihydroxybenzophenone is reacted with phosgene (first linker moiety), bisphenol-A (diol chain extender), p-cumylphenol (end-capping agent), and a secondary linker moiety (1,1,1-tris-hydroxyphenylethane (THPE)). A copolymer is thus formed.

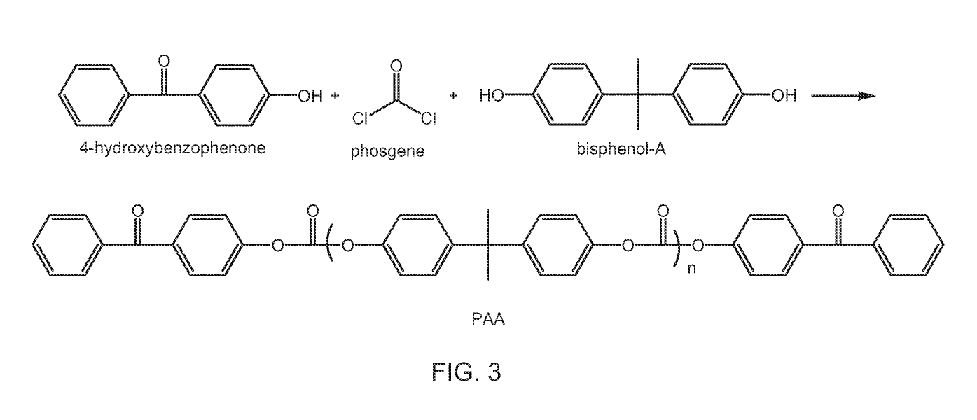

FIG. 3 illustrates the formation of another cross-linkable polycarbonate. Here, 4-hydroxybenzophenone is reacted with phosgene (first linker moiety) and bisphenol-A (diol chain extender) to obtain the cross-linkable polycarbonate resin.

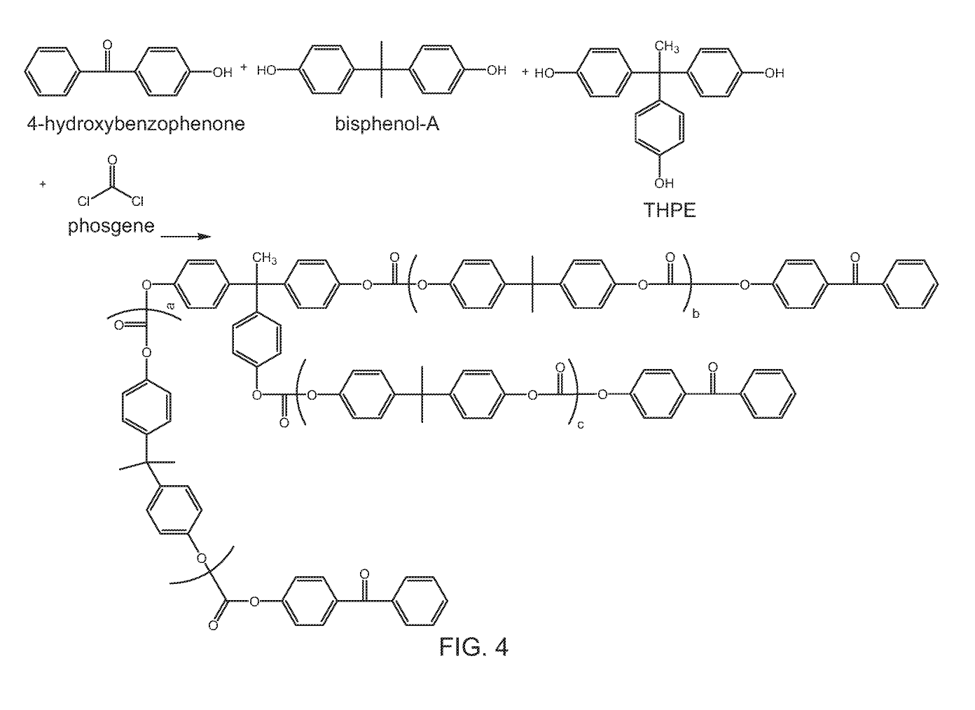

FIG. 4 illustrates the formation of a cross-linkable polycarbonate. As shown here, 4-hydroxybenzophenone is reacted with phosgene (first linker moiety), bisphenol-A (diol chain extender), p-cumylphenol (end-capping agent), and a secondary linker moiety (THPE).

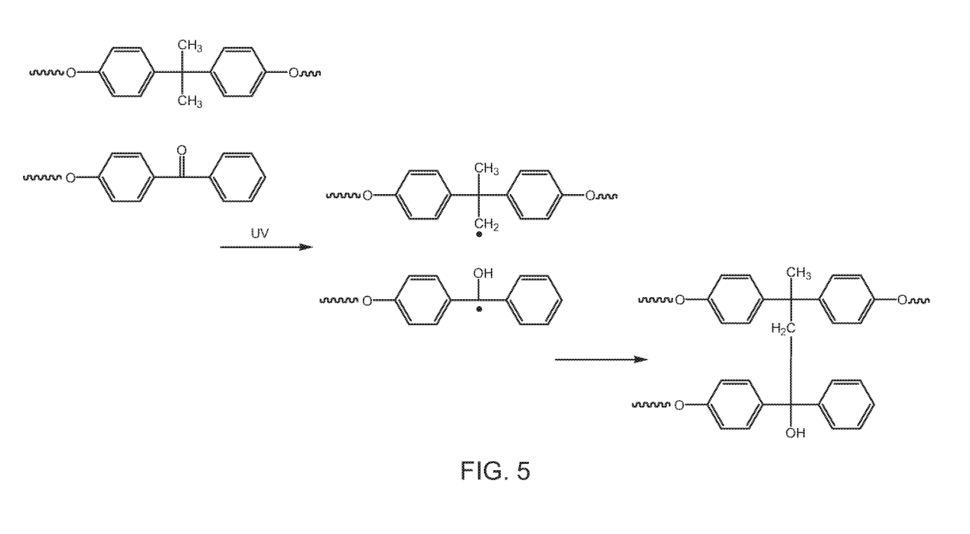

One crosslinking mechanism of the photoactive additives is believed to be due to hydrogen abstraction by the ketone group from an alkyl group that acts as a hydrogen donor and subsequent coupling of the resulting radicals. This mechanism is illustrated in FIG. 5 with reference to a benzophenone (the photoactive moiety) and a bisphenol-A (BPA) monomer. Upon exposure to UV, the oxygen atom of the benzophenone abstracts a hydrogen atom from a methyl group on the BPA monomer and becomes a hydroxyl group. The methylene group then forms a covalent bond with the carbon of the ketone group. Put another way, the ketone group of the benzophenone could be considered to be a photoactive group. It should be noted that the presence of hydrogen is critical for this reaction to occur. Other mechanisms may occur after the initial abstraction event with base resins containing unsaturated bonds or reactive side groups.

In some embodiments, the photoactive additive is a cross-linkable polycarbonate resin comprising repeating units derived from a dihydroxybenzophenone monomer (i.e. of Formula (II)). The cross-linkable polycarbonate resin may comprise from about 0.5 mole % to about 50 mole % of repeating units derived from the dihydroxybenzophenone. In more particular embodiments, the cross-linkable polycarbonate resin comprises from about 1 mole % to about 3 mole %, or from about 1 mole % to about 5 mole %, or from about 1 mole % to about 6 mole %, or from about 5 mole % to about 20 mole %, or from about 10 mole % to about 20 mole %, or from about 0.5 mole % to about 25 mole % of repeating units derived from the dihydroxybenzophenone. In more specific embodiments, the photoactive cross-linkable polycarbonate resin is a copolymer formed from the dihydroxybenzophenone, a diol chain extender, phosgene, and one or more end-capping agents. Most desirably, the dihydroxybenzophenone is 4,4′-dihydroxybenzophenone. Usually, the diol chain extender is bisphenol-A. In particular embodiments, the cross-linkable polycarbonate is a copolymer consisting of repeating units derived from 4,4′-dihydroxybenzophenone and bisphenol-A, with endcaps that are not photoactive. The copolymer contains from about 0.5 mole % to 50 mole % of repeating units derived from the dihydroxybenzophenone, and from about 50 mole % to 99.5 mole % of repeating units derived from the bisphenol-A.

In other embodiments, the photoactive additive is a cross-linkable polycarbonate resin comprising repeating units derived from a monohydroxybenzophenone monomer (i.e. of Formula (I)). The cross-linkable polycarbonate may comprise about 0.5 mole % to about 5 mole % endcap groups derived from the monohydroxybenzophenone, including from about 1 mole % to about 3 mole, or from about 1.7 mole % to about 2.5 mole %, or from about 2 mole % to about 2.5 mole %, or from about 2.5 mole % to about 3.0 mole %, or from about 3.5 mole % to about 4.0 mole % endcap groups derived from the monohydroxybenzophenone. In more specific embodiments, the photoactive cross-linkable polycarbonate resin is a homopolymer formed from the monohydroxybenzophenone, a diol chain extender, and phosgene. Most desirably, the dihydroxybenzophenone is 4-hydroxybenzophenone. Usually, the diol chain extender is bisphenol-A. In particular embodiments, the cross-linkable polycarbonate is a bisphenol-A homopolycarbonate consisting of repeating units derived from bisphenol-A, with the photoactive monohydroxybenzophenone endcaps.

In particular embodiments, the photoactive cross-linkable polycarbonate contains about 0.5 mole % of endcaps derived from a monohydroxybenzophenone, and has a weight-average molecular weight (Mw) from 17,000 to 30,000 Daltons. In other specific embodiments, the photoactive cross-linkable polycarbonate contains about 2.5 mole % of endcaps derived from a monohydroxybenzophenone, and has a weight-average molecular weight (Mw) from 24,000 to 31,000 Daltons. In still other definite embodiments, the photoactive cross-linkable polycarbonate has an MVR of 8 to 10 cc/10 min at 300° C./1.2 kg.

These polycarbonates, prior to cross-linking, can be provided as thermally stable high melt-flow polymers, and can thus be used to fabricate a variety of thin-walled articles (e.g., 3 mm or less). These articles are subsequently exposed to ultraviolet radiation to affect cross-linking. The cross-linked materials, in addition to flame resistance and chemical resistance, may retain or exhibit superior mechanical properties (e.g., impact resistance, ductility) as compared to the polycarbonate resin prior to cross-linking.

The cross-linkable polycarbonates of the present disclosure may have a glass transition temperature (Tg) of greater than 120° C., 125° C., 130° C., 135° C., 140° C., 145° C., 150° C., 155° C., 160° C., 165° C., 170° C., 175° C., 180° C., 185° C., 190° C., 200° C., 210° C., 220° C., 230° C., 240° C., 250° C., 260° C., 270° C., 280° C., 290° C., or 300° C., as measured using a differential scanning calorimetry method. In certain embodiments, the polycarbonates have glass transition temperatures ranging from about 120° C. to about 230° C., about 140° C. to about 160° C., about 145° C. to about 155° C., about 148° C. to about 152° C., or about 149° C. to about 151° C.

The cross-linkable polycarbonates of the present disclosure may have a weight average molecular weight (Mw) of 15,000 to about 80,000 Daltons [±1,000 Daltons], or of 15,000 to about 35,000 Daltons [±1,000 Daltons], or of about 20,000 to about 30,000 Daltons [±1,000 Daltons], or of 17,000 to about 80,000 Daltons. Molecular weight determinations may be performed using gel permeation chromatography (GPC), using a cross-linked styrene-divinylbenzene column and calibrated to polycarbonate references using a UV-VIS detector set at 264 nm. Samples may be prepared at a concentration of about 1 milligrams per milliliter (mg/ml), and eluted at a flow rate of about 1.0 milliliter per minute (ml/min).

The cross-linkable polycarbonates of the present disclosure may have a polydispersity index (PDI) of about 2.0 to about 5.0, about 2.0 to about 3.0, or about 2.0 to about 2.5. The PDI is measured prior to any UV exposure.

The cross-linkable polycarbonates of the present disclosure may have a melt flow rate (MFR) of 1 to 45 grams/10 min, 6 to 15 grams/10 min, 6 to 8 grams/10 min, 6 to 12 grams/10 min, 2 to 30 grams/10 min, 5 to 30 grams/10 min, 8 to 12 grams/10 min, 8 to 10 grams/10 min, or 20 to 30 grams/10 min, using the ASTM D1238-13 method, 1.2 kg load, 300° C. temperature, 360 second dwell.

The cross-linkable polycarbonates of the present disclosure may have a biocontent of 2 wt % to 90 wt %; 5 wt % to 25 wt %; 10 wt % to 30 wt %; 15 wt % to 35 wt %; 20 wt % to 40 wt %; 25 wt % to 45 wt %; 30 wt % to 50 wt %; 35 wt % to 55 wt %; 40 wt % to 60 wt %; 45 wt % to 65 wt %; 55 wt % to 70% wt %; 60 wt % to 75 wt %; 50 wt % to 80 wt %; or 50 wt % to 90 wt %. The biocontent may be measured according to ASTM D6866-10.

The cross-linkable polycarbonates of the present disclosure may have a modulus of elasticity of greater than or equal to (≧)2200 megapascals (MPa), ≧2310 MPa, ≧2320 MPa, ≧2330 MPa, ≧2340 MPa, ≧2350 MPa, ≧2360 MPa, ≧2370 MPa, ≧2380 MPa, ≧2390 MPa, ≧2400 MPa, ≧2420 MPa, ≧2440 MPa, ≧2460 MPa, ≧2480 MPa, ≧2500 MPa, or ≧2520 MPa as measured by ASTM D790-10 at 1.3 mm/min, 50 mm span.

In embodiments, the cross-linkable polycarbonates of the present disclosure may have a flexural modulus of 2,200 to 2,500, preferably 2,250 to 2,450, more preferably 2,300 to 2,400 MPa. In other embodiments, the cross-linkable polycarbonates of the present disclosure may have a flexural modulus of 2,300 to 2,600, preferably 2,400 to 2,600, more preferably 2,450 to 2,550 MPa. The flexural modulus is also measured by ASTM D790-10.

The cross-linkable polycarbonates of the present disclosure may have a tensile strength at break of greater than or equal to (≧)60 megapascals (MPa), ≧61 MPa, ≧62 MPa, ≧63 MPa, ≧64 MPa, ≧65 MPa, ≧66 MPa, ≧67 MPa, ≧68 MPa, ≧69 MPa, ≧70 MPa, ≧71 MPa, ≧72 MPa, ≧73 MPa, ≧74 MPa, ≧75 MPa as measured by ASTM D638-10 Type I at 50 mm/min.

The cross-linkable polycarbonates of the present disclosure may possess a ductility of greater than or equal to (≧)60%, ≧65%, ≧70%, ≧75%, ≧80%, ≧85%, ≧90%, ≧95%, or 100% in a notched izod test at −20° C., −15° C., −10° C., 0° C., 5° C., 10° C., 15° C., 20° C., 23° C., 25° C., 30° C., or 35° C. at a thickness of 3.2 mm according to ASTM D256-10.

The cross-linkable polycarbonates of the present disclosure may have a notched Izod impact strength (NII) of ≧500 Joules per meter (J/m), ≧550 J/m, ≧600 J/m, ≧650 J/m, ≧700 J/m, ≧750 J/m, ≧800 J/m, ≧850 J/m, ≧900 J/m, ≧950 J/m, or ≧1000 J/m, measured at 23° C. according to ASTM D256-10.

The cross-linkable polycarbonates of the present disclosure may have a heat distortion temperature of greater than or equal to 110° C., 111° C., 112° C., 113° C., 114° C., 115° C., 116° C., 117° C., 118° C., 119° C., 120° C., 121° C., 122° C., 123° C., 124° C., 125° C., 126° C., 127° C., 128° C., 129° C., 130° C., 131° C., 132° C., 133° C., 134° C., 135° C., 136° C., 137° C., 138° C., 139° C., 140° C., 141° C., 142° C., 143° C., 144° C., 145° C., 146° C., 147° C., 148° C., 149° C., 150° C., 151° C., 152° C., 153° C., 154° C., 155° C., 156° C., 157° C., 158° C., 159° C., 160, 161° C., 162° C., 163° C., 164° C., 165° C., 166° C., 167° C., 168° C., 169° C., or 170° C., as measured according to ASTM D648-07 at 1.82 MPa, with 3.2 mm thick unannealed mm bar.

The cross-linkable polycarbonates of the present disclosure may have a percent haze value of less than or equal to (≦)10.0%, ≦8.0%, ≦6.0%, ≦5.0%, ≦4.0%, ≦3.0%, ≦2.0%, ≦1.5%, ≦1.0%, or ≦0.5% as measured at a certain thickness according to ASTM D1003-13. The polycarbonate haze may be measured at a 2.0, 2.2, 2.4, 2.54, 2.6, 2.8, 3.0, 3.2, 3.4, 3.6, 3.8, or a 4.0 millimeter thickness. The polycarbonate may be measured at a 0.125 inch thickness.

The polycarbonate may have a light transmittance greater than or equal to (≧) 50%, ≧60%, ≧65%, ≧70%, ≧75%, ≧80%, ≧85%, ≧90%, ≧95%, ≧96%, ≧97%, ≧98%, ≧99%, ≧99.1%, ≧99.2%, ≧99.3%, ≧99.4%, ≧99.5%, ≧99.6%, ≧99.7%, ≧99.8%, or ≧99.9%, as measured at certain thicknesses according to ASTM D1003-13. The polycarbonate transparency may be measured at a 2.0, 2.2, 2.4, 2.6, 2.8, 3.0, 3.2, 3.4, 3.6, 3.8, or a 4.0 millimeter thickness.

In certain embodiments, the cross-linkable polycarbonates of the present disclosure do not include soft block or soft aliphatic segments in the polycarbonate chain. For example, the following aliphatic soft segments that may be excluded from the cross-linkable polycarbonates of the present disclosure include aliphatic polyesters, aliphatic polyethers, aliphatic polythioeithers, aliphatic polyacetals, aliphatic polycarbonates, C—C linked polymers and polysiloxanes. The soft segments of aliphatic polyesters, aliphatic polyethers, aliphatic polythioeithers, aliphatic polyacetals, aliphatic polycarbonates may be characterized as having number average molecular weight (Mns) of greater than 600 Daltons.

Processes

An interfacial polycondensation polymerization process for bisphenol-A (BPA) based polycarbonates can be used to prepare the photoactive additives (PAAs) of the present disclosure. Although the reaction conditions for interfacial polymerization can vary, an exemplary process generally involves dissolving or dispersing one or more dihydric phenol reactants (e.g. bisphenol-A) in water, adding the resulting mixture to a water-immiscible solvent medium, and contacting the reactants with a carbonate precursor (e.g. phosgene) in the presence of a catalyst (e.g. triethylamine, TEA).

Four different processes are disclosed herein for producing some embodiments of the photoactive additive which contain carbonate linkages. Each process includes the following ingredients: a diol chain extender, an end-capping agent, a carbonate precursor, a base, a tertiary amine catalyst, water, and a water-immiscible organic solvent, and optionally a branching agent. It should be noted that more than one of each ingredient can be used to produce the photoactive additive. Some information on each ingredient is first provided below.

A hydroxybenzophenone is present as the photoactive moiety, and can be present either as the end-capping agent (i.e. monohydroxybenzophenone) or as a diol (i.e. dihydroxybenzophenone). In the process descriptions below, reference will be made to diols, which should be construed as including the diol chain extender and a dihydroxybenzophenone monomer. Reference will also be made to the end-capping agent, which should be construed as including a monohydroxybenzophenone.

The diol chain extender may have the structure of any one of Formulas (A)-(H), and include monomers such as bisphenol-A.

Examples of end-capping agents (other than the monohydroxybenzophenone) include phenol, p-cumylphenol (PCP), p-tert-butylphenol, octylphenol, and p-cyanophenol.

The carbonate precursor may be, for example, a carbonyl halide such as carbonyl dibromide or carbonyl dichloride (also known as phosgene), or a haloformate such as a bishaloformate of a dihydric phenol (e.g., the bischloroformate of bisphenol-A, hydroquinone, or the like) or a glycol (e.g., the bishaloformate of ethylene glycol, neopentyl glycol, polyethylene glycol, or the like). Combinations comprising at least one of the foregoing types of carbonate precursors can also be used. In certain embodiments, the carbonate precursor is phosgene, a triphosgene, diacyl halide, dihaloformate, dicyanate, diester, diepoxy, diarylcarbonate, dianhydride, diacid chloride, or any combination thereof. An interfacial polymerization reaction to form carbonate linkages may use phosgene as a carbonate precursor, and is referred to as a phosgenation reaction. The compounds of Formulas (3) or (4) are carbonate precursors.

The base is used for the regulation of the pH of the reaction mixture. In particular embodiments, the base is an alkali metal hydroxide, such as sodium hydroxide (NaOH) or potassium hydroxide (KOH).

A tertiary amine catalyst is used for polymerization. Exemplary tertiary amine catalysts that can be used are aliphatic tertiary amines such as triethylamine (TEA)), N-ethylpiperidine, 1,4-diazabicyclo[2.2.2]octane (DABCO), tributylamine, cycloaliphatic amines such as N,N-diethyl-cyclohexylamine and aromatic tertiary amines such as N,N-dimethylaniline.

Sometimes, a phase transfer catalyst is also used. Among the phase transfer catalysts that can be used are catalysts of the formula (R³⁰)₄Q⁺X, wherein each R³⁰ is the same or different, and is a C₁-C₁₀ alkyl group; Q is a nitrogen or phosphorus atom; and X is a halogen atom, C₁-C₈ alkoxy group, or C₆-C₁₈ aryloxy group. Exemplary phase transfer catalysts include, for example, [CH₃(CH₂)₃]₄NX, [CH₃(CH₂)₃]₄PX, [CH₃(CH₂)₅]₄NX, [CH₃(CH₂)₆]₄NX, [CH₃(CH₂)₄]₄NX, CH₃[CH₃(CH₂)₃]₃NX, and CH₃[CH₃(CH₂)₂]₃NX, wherein X is Cl⁻, Br⁻, a C₁-C₈ alkoxy group or a C₆-C₁₈ aryloxy group, such as methyltributylammonium chloride.

The most commonly used water-immiscible solvents include methylene chloride, 1,2-dichloroethane, chlorobenzene, toluene, and the like.

In the first process, sometimes referred to as the “upfront” process, the diol(s), end-capping agent, catalyst, water, and water-immiscible solvent are combined upfront in a vessel to form a reaction mixture. The reaction mixture is then exposed to the carbonate precursor, for example by phosgenation, while the base is co-added to regulate the pH, to obtain the photoactive additive.

The pH of the reaction mixture is usually from about 8.5 to about 10, and can be maintained by using a basic solution (e.g. aqueous NaOH). The reaction mixture is then charged with the carbonate precursor, which is usually phosgene. The carbonate precursor is added to the reaction mixture over a period of about 15 minutes to about 45 minutes. While the carbonate precursor is being added, the pH is also maintained in the range of about 8.5 to about 10, again by addition of a basic solution as needed. The cross-linkable polycarbonate is thus obtained, and is then isolated from the reaction mixture.

In the second process, also known as the “solution addition” process, the diol(s), tertiary amine catalyst, water, and water-immiscible solvent are combined in a vessel to form a reaction mixture. The total charge of the carbonate precursor is then added to this reaction mixture in the vessel over a total time period, while the base is co-added to regulate the pH. The carbonate precursor is first added to the reaction mixture along with the base to regulate the pH for a first time period. After the first time period ends, the end-capping agent is added in a controlled manner to the reaction mixture, also referred to as programmed addition. The addition of the end-capping agent occurs for a second time period after the first time period, rather than as a bolus at the beginning of the reaction (as in the upfront process). The carbonate precursor and the base are also added concurrently with the end-capping agent during the second time period. After the second time period ends, the remainder of the carbonate precursor continues uninterrupted for a third time period until the total charge is reached. The base is also co-added during the third time period to regulate the reaction pH. The pH of the reaction mixture is usually from about 8.5 to about 10, and can be maintained by using a basic solution (e.g. aqueous NaOH, made from the base). The end-capping agent is not added during either the first time period or the third time period. The photoactive additive is thus obtained. The main difference between the first and second processes is in the addition of the end-capping agent over time.

In the second process, the carbonate precursor is added to the reaction mixture over a total time period, which may be for example from about 15 minutes to about 45 minutes. The total time period is the duration needed to add the total charge of the carbonate precursor (measured either by weight or by moles) to the reaction mixture. It is contemplated that the carbonate precursor is added at a constant rate over the total time period. The carbonate precursor is first added to the reaction mixture along with the base to regulate the pH for a first time period, ranging from about 2 minutes to about 20 minutes. Then, during a second time period, the end-capping agent is added to the reaction mixture concurrently with the carbonate precursor and the base. It is contemplated that the end-capping agent is added at a constant rate during this second time period, which can range from about 1 minute to about 5 minutes. After the second time period ends, the remaining carbonate precursor is charged to the reaction mixture for a third time period, along with the base to regulate the reaction pH. The cross-linkable polycarbonate is thus obtained, and is then isolated from the reaction mixture.

The total time period for the reaction is the sum of the first time period, the second time period, and the third time period. In particular embodiments, the second time period in which the solution containing the end-capping agent is added to the reaction mixture begins at a point between 10% to about 40% of the total time period. Put another way, the first time period is 10% of the total time period.

For example, if 2400 grams of phosgene were to be added to a reaction mixture at a rate of 80 grams per minute (g/min), and 500 ml of a PCP solution were to be added to the reaction mixture at a rate of 500 ml/min after an initial charge of 240 grams of phosgene, then the total time period would be 30 minutes, the first time period would be three minutes, the second time period would be one minute, and the third period would be 26 minutes.

The third process is also referred to as a bis-chloroformate or chlorofomate (BCF) process. Chloroformate oligomers are prepared by reacting the carbonate precursor, specifically phosgene, with the diol(s) in the absence of the tertiary amine catalyst, while the base is co-added to regulate the pH. The chloroformate oligomers can contain a mixture of monochloroformates, bischloroformates, and bisphenol terminated oligomers. After the chloroformate oligomers are generated, the phosgene can optionally be allowed to substantially condense or hydrolyze, then the end-capping agent is added to the chloroformate mixture. The reaction is allowed to proceed, and the tertiary amine catalyst is added to complete the reaction. The pH of the reaction mixture is usually from about 8.5 to about 10 prior to the addition of the phosgene. During the addition of the phosgene, the pH is maintained between about 6 and about 8, by using a basic solution (e.g. aqueous NaOH).

The fourth process uses a tubular reactor. In the tubular reactor, the end-capping agent is pre-reacted with the carbonate precursor (specifically phosgene) to form chloroformates. The water-immiscible solvent is used as a solvent in the tubular reactor. In a separate reactor, the diol(s), tertiary amine catalyst, water, and water-immiscible solvent are combined to form a reaction mixture. The chloroformates in the tubular reactor are then fed into the reactor over a first time period along with additional carbonate precursor to complete the reaction while the base is co-added to regulate the pH. During the addition of the chloroformates, the pH is maintained between about 8.5 and about 10, by using a basic solution (e.g. aqueous NaOH).

The resulting cross-linkable polycarbonate formed by any of these processes contains only a small amount of low-molecular-weight components. This can be measured in two different ways: the level of diarylcarbonates (DAC) and the lows percentage can be measured. Diarylcarbonates are formed by the reaction of two end-capping agents with phosgene, creating a small molecule. In embodiments, the resulting photoactive additive contains less than 1000 ppm of diarylcarbonates. The lows percentage is the percentage by weight of oligomeric chains having a molecular weight of less than 1000. In embodiments, the lows percentage is 2.0 wt % or less, including from about 1.0 wt % to 2.0 wt %. The DAC level and the lows percentage can be measured by high performance liquid chromatography (HPLC) or gel permeation chromatography (GPC). Also of note is that the resulting photoactive additive does not contain any residual pyridine, because pyridine is not used in the manufacture of the photoactive additive.

Blends with Second Polymer Resin

The photoactive additive can be blended with a polymeric base resin that is different from the photoactive additive, i.e. a second polymer resin, to form the polymeric compositions/blends of the present disclosure. More specifically, the second polymer resin does not contain photoactive groups. In embodiments, the weight ratio of the cross-linkable polycarbonate resin to the polymeric base resin is from 1:99 to 99:1. When the additive contains a monohydroxybenzophenone, the weight ratio of the cross-linkable polycarbonate resin to the polymeric base resin may be from about 50:50 to about 95:5. When the additive contains a dihydroxybenzophenone, the weight ratio of the cross-linkable polycarbonate resin to the polymeric base resin may be from about 10:90 to about 85:15, or from about 25:75 to about 50:50. The polymeric base resin has, in specific embodiments, a weight-average molecular weight of about 21,000 Daltons or greater, including from about 21,000 to about 40,000 Daltons.

The cross-linkable polycarbonate resins are suitable for blending with polycarbonate homopolymers, polycarbonate copolymers, and polycarbonate blends. They are also suitable for blending with polyesters, polyarylates, polyestercarbonates, and polyetherimides.

The blends may comprise one or more distinct cross-linkable polycarbonates, as described herein, and/or one or more cross-linked polycarbonate(s). The blends also comprise one or more additional polymers. The blends may comprise additional components, such as one or more additives. In certain embodiments, a blend comprises a cross-linkable and/or cross-linked polycarbonate (Polymer A) and a second polymer (Polymer B), and optionally one or more additives. In another embodiment, a blend comprises a combination of a cross-linkable and/or cross-linked polycarbonate (Polymer A); and a second polycarbonate (Polymer B), wherein the second polycarbonate is different from the first polycarbonate.

The second polymer (Polymer B) may be any polymer different from the first polymer that is suitable for use in a blend composition. In certain embodiments, the second polymer may be a polyester, a polyestercarbonate, a bisphenol-A homopolycarbonate, a polycarbonate copolymer, a tetrabromo-bisphenol A polycarbonate copolymer, a polysiloxane-co-bisphenol-A polycarbonate, a polyesteramide, a polyimide, a polyetherimide, a polyamideimide, a polyether, a polyethersulfone, a polyepoxide, a polylactide, a polylactic acid (PLA), or any combination thereof.

In certain embodiments, the polymeric base resin may be a vinyl polymer, a rubber-modified graft copolymer, an acrylic polymer, polyacrylonitrile, a polystyrene, a polyolefin, a polyester, a polyesteramide, a polysiloxane, a polyurethane, a polyamide, a polyamideimide, a polysulfone, a polyepoxide, a polyether, a polyimide, a polyetherimide, a polyphenylene ether, a polyphenylene sulfide, a polyether ketone, a polyether ether ketone, an acrylonitrile-butadiene-styrene (ABS) resin, an acrylic-styrene-acrylonitrile (ASA) resin, a polyethersulfone, a polyphenylsulfone, a poly(alkenylaromatic) polymer, a polybutadiene, a polyacetal, a polycarbonate, a polyphenylene ether, an ethylene-vinyl acetate copolymer, a polyvinyl acetate, a liquid crystal polymer, an ethylene-tetrafluoroethylene copolymer, an aromatic polyester, a polyvinyl fluoride, a polyvinylidene fluoride, a polyvinylidene chloride, tetrafluoroethylene, a polylactide, a polylactic acid (PLA), a polycarbonate-polyorganosiloxane block copolymer, or a copolymer comprising: (i) an aromatic ester, (ii) an estercarbonate, and (iii) carbonate repeat units. The blend composition may comprise additional polymers (e.g. a third, fourth, fifth, sixth, etc., polymer).

In certain embodiments, the polymeric base resin may be a homopolycarbonate, a copolycarbonate, a polycarbonate-polysiloxane copolymer, a polyester-polycarbonate, or any combination thereof. In certain embodiments, the polymeric base resin is a p-cumyl phenol capped poly(isophthalate-terephthalate-resorcinol ester)-co-(bisphenol-A carbonate) copolymer. In certain embodiments, the polymeric base resin is a polycarbonate-polysiloxane copolymer.

The p-cumyl phenol capped poly(isophthalate-terephthalate-resorcinol ester)-co-(bisphenol-A carbonate) polymer or a polycarbonate-polysiloxane copolymer may have a polysiloxane content from 0.4 wt % to 25 wt %. In one preferred embodiment, the polymeric base resin is a p-cumylphenol capped poly(19 mole % isophthalate-terephthalate-resorcinol ester)-co-(75 mole % bisphenol-A carbonate)-co-(6 mole % resorcinol carbonate) copolymer (Mw=29,000 Daltons). In another preferred embodiment, the polymeric base resin is a p-cumylphenol capped poly(10 wt % isophthalate-terephthalate-resorcinol ester)-co-(87 wt % bisphenol-A carbonate)-co-(3 mole % resorcinol carbonate) copolymer (Mw=29,000 Daltons).

In another preferred embodiment, the polymeric base resin is a polycarbonate polysiloxane copolymer. The polycarbonate-polysiloxane copolymer may be a siloxane block co-polycarbonate comprising from about 4 wt % siloxane (±10%) to about 25 wt % siloxane (±10%) and having a siloxane chain length of 10 to 200. In another preferred embodiment, the polymeric base resin is a PC-siloxane copolymer with 20% siloxane segments by weight.

In another preferred embodiment, the polymeric base resin is a p-cumylphenol capped poly(65 mole % BPA carbonate)-co-(35 mole % 3,3-bis(4-hydroxyphenyl)-2-phenylisoindolin-1-one (PPPBP) carbonate) copolymer (Mw=25,000 Daltons).

In another preferred embodiment, the polymeric base resin is a polyphosphonate polymer, a polyphosphonate copolymer, or a poly(polyphosphonate)-co-(BPA carbonate) copolymer.

In yet other embodiments, the polymer resin in the blend is selected from the group consisting of a polycarbonate-polysiloxane copolymer; a polycarbonate resin having an aliphatic chain containing at least two carbon atoms as a repeating unit in the polymer backbone; a copolyester polymer; a bisphenol-A homopolycarbonate; a polystyrene polymer; a poly(methyl methacrylate) polymer; a thermoplastic polyester; a polybutylene terephthalate polymer; a methyl methacrylate-butadiene-styrene copolymer; an acrylonitrile-butadiene-styrene copolymer; a dimethyl bisphenol cyclohexane-co-bisphenol-A copolymer; a polyetherimide; a polyethersulfone; and a copolycarbonate of bisphenol-A and 1,1-bis(4-hydroxyphenyl)-3,3,5-trimethylcyclohexane) (BPTMC).

In particular embodiments, the polymer resin in the blend is a polycarbonate-polysiloxane (PC—Si) copolymer. The polycarbonate units of the copolymer are derived from dihydroxy compounds having the structures of any of the formulas described above, but particularly those of the chain extenders of Formulas (A) and (B). Some illustrative examples of suitable dihydroxy compounds include the following: 1,1-bis(4-hydroxyphenyl) methane, 1,1-bis(4-hydroxyphenyl) ethane, 2,2-bis(4-hydroxyphenyl) propane (hereinafter “bisphenol-A” or “BPA”), 2,2-bis(4-hydroxyphenyl) butane, 2,2-bis(4-hydroxyphenyl) octane, 1,1-bis(4-hydroxyphenyl) propane, 1,1-bis(4-hydroxyphenyl) n-butane, 2,2-bis(4-hydroxy-1-methylphenyl) propane, and 1,1-bis(4-hydroxy-t-butylphenyl) propane; resorcinol, substituted resorcinol compounds such as 5-methyl resorcinol, 5-phenyl resorcinol, or 5-cumyl resorcinol; catechol; hydroquinone; and substituted hydroquinones such as 2-methyl hydroquinone, 2-t-butyl hydroquinone, 2-phenyl hydroquinone, 2-cumyl hydroquinone, or 2,3,5,6-tetramethyl hydroquinone. Bisphenol-A is often part of the PC—Si copolymer.

The polymer resin (polymer B) in the blend can be a polycarbonate resin having an aliphatic chain containing at least two carbon atoms as a repeating unit in the polymer backbone. This resin can also be considered a “soft segment polycarbonate” (SSP) resin. Generally speaking, the SSP resin is a copolymer of an aromatic difunctional compound and an aliphatic difunctional compound. The aromatic difunctional compound may have the structure of, for example, any of Formulas (A)-(H), previously described as chain extenders above. In specific embodiments, the aromatic difunctional compound is a bisphenol of Formula (A). The aliphatic difunctional compound provides a long aliphatic chain in the backbone and may have the structure of Formula (E). Exemplary aliphatic diols that are useful in SSP resins include adipic acid (n=4), sebacic acid (n=8), and dodecanedioic acid (n=10). The SSP resin can be formed, for example by the phosgenation of bisphenol-A, sebacic acid, and p-cumyl phenol. The SSP resin contains carbonate linkages and ester linkages.

In this regard, it is believed that the cross-linking reaction rate of the cross-linkable polycarbonate resin and its yield are directly related to the hydrogen-to-ketone ratio of the polymeric blend. Thus, the higher the hydrogen-to-ketone ratio of the blend, the higher the rate of chain-extension reaction/crosslinking should be. Due to the presence of the hydrogen-rich SSP resin with its aliphatic blocks, the hydrogen-to-ketone ratio is relatively high. As a result, the crosslinking density and the resulting flame retardance and chemical resistance should be very good for this blend. In addition, the SSP resin has very good flow properties. It is believed that the blend should also have good flow, and should also retain its ductile properties even after crosslinking.

The polymer resin (polymer B) in the blend can be a bisphenol-A homopolycarbonate. Such resins are available, for example as LEXAN from SABIC Innovative Plastics.

The polymer resin (polymer B) in the blend can be a polystyrene polymer. Such polymers contain only polystyrene monomers. Thus, for example ABS and MBS should not be considered polystyrene polymers.

The polymer resin (polymer B) in the blend can be a thermoplastic polyester. An exemplary polyester is PCTG, which is a copolymer derived from the reaction of terephthalic acid, ethylene glycol, and cyclohexanedimethanol (CHDM). The PCTG copolymer can contain 40-90 mole % CHDM, with the terephthalic acid and the ethylene glycol making up the remaining 10-60 mole %.

The polymer resin (polymer B) in the blend can be a dimethyl bisphenol cyclohexane-co-bisphenol-A copolymer, i.e. a DMBPC-BPA copolymer. The DMBPC is usually from 20 mole % to 90 mole % of the copolymer, including 25 mole % to 60 mole %. The BPA is usually from 10 mole % to 80 mole % of the copolymer, including 40 mole % to 75 mole %. These resins have high scratch resistance.

Other Additives

Other conventional additives can also be added to the polymeric composition (e.g. an impact modifier, UV stabilizer, colorant, flame retardant, heat stabilizer, plasticizer, lubricant, mold release agent, filler, reinforcing agent, antioxidant agent, antistatic agent, blowing agent, or radiation stabilizer).

In preferred embodiments, the blend compositions disclosed herein comprise a flame-retardant, a flame retardant additive, and/or an impact modifier. The flame-retardant may be potassium perfluorobutane sulfonate (Rimar salt), potassium diphenyl sulfone-3-sulfonate (KSS), or a combination thereof.

Various types of flame retardants can be utilized as additives. This includes flame retardant salts such as alkali metal salts of perfluorinated C₁-C₁₆ alkyl sulfonates such as potassium perfluorobutane sulfonate (Rimar salt), potassium perfluoroctane sulfonate, tetraethylammonium perfluorohexane sulfonate, potassium diphenylsulfone sulfonate (KSS), and the like, sodium benzene sulfonate, sodium toluene sulfonate (NATS) and the like. Rimar salt and KSS and NATS, alone or in combination with other flame retardants, are particularly useful in the compositions disclosed herein. In certain embodiments, the flame retardant does not contain bromine or chlorine, i.e. is non-halogenated. Another useful class of flame retardant is the class of cyclic siloxanes having the general formula [(R)₂SiO]_{y} wherein R is a monovalent hydrocarbon or fluorinated hydrocarbon having from 1 to 18 carbon atoms and y is a number from 3 to 12. A particularly useful cyclic siloxane is octaphenylcyclotetrasiloxane.

Exemplary heat stabilizer additives include, for example, organophosphites such as triphenyl phosphite, tris-(2,6-dimethylphenyl)phosphite, tris-(mixed mono- and di-nonylphenyl)phosphite or the like; phosphonates such as dimethylbenzene phosphonate or the like; phosphates such as trimethyl phosphate, or the like; or combinations comprising at least one of the foregoing heat stabilizers. Heat stabilizers are generally used in amounts of 0.0001 to 1 part by weight, based on 100 parts by weight of the polymer component of the polymeric blend/composition.

Mold release agent (MRA) will allow the material to be removed quickly and effectively. Mold releases can reduce cycle times, defects, and browning of finished product. Exemplary MRAs include phthalic acid esters; di- or polyfunctional aromatic phosphates such as resorcinol tetraphenyl diphosphate (RDP), the bis(diphenyl) phosphate of hydroquinone and the bis(diphenyl) phosphate of bisphenol-A; pentaerythritol tetrastearate (PETS), and the like. Such materials are generally used in amounts of 0.001 to 1 part by weight, specifically 0.01 to 0.75 part by weight, more specifically 0.1 to 0.5 part by weight, based on 100 parts by weight of the polymer component of the polymeric blend/composition.

In particular embodiments, the polymeric blend/composition includes the cross-linkable polycarbonate resin, an optional polymeric base resin, and a flame retardant which is Rimar salt and which is present in an amount of about 0.05 wt % to about 0.085 wt %, based on the total weight of the composition; and a plaque comprising the polymeric composition has a transparency of 70 to 90% at a thickness of 3.2 mm, measured according to ASTM D1003-13.

In other particular embodiments, the polymeric blend/composition includes the cross-linkable polycarbonate resin, an optional polymeric base resin, a flame retardant; a heat stabilizer, and a mold release agent.

The additives, when used, can improve various properties of the final article. Increased chemical resistance may be found against 409 Glass and Surface Cleaner; Alcohol Prep Pad; CaviCide liquid/CaviWipes; CaviWipes; Cidex Plus liquid; Clorox Bleach; Clorox Wipes; Envirocide liquid; ForPro liquid; Gentle dish soap and water; Hydrogen Peroxide Cleaner Disinfectant Wipes; Isopropyl Alcohol wipes; MadaCide-1 liquid; Mar-V-Cide liquid to dilute; Sani-Cloth Bleach Wipes; Sani-Cloth HB Wipes; Sani-Cloth Plus Wipes; Sodium Hypochlorite liquid; Super Sani-Cloth Wipes; Viraguard liquid and Wipes; Virex 256; Windex Blue; Fuel C; Toluene; Heptane; Ethanol; Isopropanol; Windex; Engine oil; WD40; Transmission fluid; Break fluid; Glass wash; Diesel; Gasoline; Banana Boat Sunscreen (SPF 30); Sebum; Ivory Dish Soap; SC Johnson Fantastik Cleaner; French's Yellow Mustard; Coca-Cola; 70% Isopropyl Alcohol; Extra Virgin Olive Oil; Vaseline Intensive Care Hand Lotion; Heinz Ketchup; Kraft Mayonnaise; Chlorox Formula 409 Cleaner; SC Johnson Windex Cleaner with Ammonia; Acetone; Artificial Sweat; Fruits & Passion Cucina Coriander & Olive Hand Cream; Loreal Studioline Megagel Hair Gel; Maybelline Lip Polish; Maybelline Expert Wear Blush—Beach Plum Rouge; Purell Hand Sanitizer; Hot coffee, black; iKlear; Chlorox Wipes; Squalene; Palmitic Acid; Oleic Acid; Palmitoleic Acid; Stearic Acid; and Olive Oil.

Articles

The compositions/blends can be molded into useful shaped articles by a variety of means such as injection molding, overmolding, co-injection molding, extrusion, multilayer extrusion, rotational molding, blow molding and thermoforming to form articles. This includes thin-walled articles, including highly transparent thin-walled articles. The formed articles may be subsequently subjected to cross-linking conditions (e.g., UV-radiation) to affect cross-linking of the polycarbonates. Exemplary articles include a film, a sheet, a layer of a multilayer film, or a layer of a multilayer sheet. These polycarbonate articles can serve as a substrate for photopatterning at selective locations, such as potential failure points, knit lines, or sharp edges, which can subsequently be crosslinked for improved mechanical properties.

Articles that may be formed from the compositions/blends include various components for cell phones and cell phone covers, components for computer housings (e.g. mouse covers), fibers, computer housings and business machine housings and parts such as housings and parts for monitors, computer routers, copiers, desk top printers, large office/industrial printers handheld electronic device housings such as computer or business machine housings, housings for hand-held devices, components for light fixtures or home or office appliances, humidifier housings, thermostat control housings air conditioner drain pans, outdoor cabinets, telecom enclosures and infrastructure, Simple Network Intrusion Detection System (SNIDS) devices, network interface devices, smoke detectors, components and devices in plenum spaces, components for medical applications or devices such as medical scanners, X-ray equipment, and ultrasound devices, components for interior or exterior components of an automobile, lenses (auto and non-auto) such as components for film applications, greenhouse components, sun room components, fire helmets, safety shields, safety goggles, glasses with impact resistance, fendors, gas pumps, films for televisions, such as ecofriendly films having no halogen content, solar application materials, glass lamination materials, fibers for glass-filled systems, hand held electronic device enclosures or parts (e.g. walkie-talkie, scanner, media/MP3/MP4 player, radio, GPS system, ebook, tablet), wearable electronic devices (e.g. smart watch, training/tracking device, activity/sleep monitoring system, wristband, or glasses), hand held tool enclosures or parts, smart phone enclosures or parts, turbine blades (e.g., wind turbines), and the like.

In certain embodiments, articles that may comprise the composition/blend include automotive bumpers, other automotive, construction and agricultural equipment exterior components, automobile mirror housings, an automobile grille, an automobile pillar, automobile wheel covers, automobile, construction and agricultural equipment instrument panels and trim, construction and agricultural grilles, automobile glove boxes, automobile door hardware and other interior trim, automobile construction and agricultural equipment exterior lights, automobile parts within the engine compartment, plumbing equipment, valves and pumps, air conditioning heating and cooling parts, furnace and heat pump parts, computer parts, electronics parts, projector parts, electronic display parts, copier parts, scanner parts, electronic printer toner cartridges, hair driers, irons, coffee makers, toasters, washing machines, microwaves, ovens, power tools, electric components, lighting parts, dental instruments and equipment, medical instruments, cookware, medical instrument trays, animal cages, fibers, laser welded medical devices, hand held electronic device enclosures or parts (e.g. walkie-talkie, scanner, media/MP3/MP4 player, radio, GPS system, ebook, tablet), wearable electronic devices (e.g. smart watch, training/tracking device, activity/sleep monitoring system, wristband, or glasses), hand held tool enclosures or parts, smart phone enclosures or parts, and fiber optics.

In certain embodiments, articles that may comprise the composition/blend include automotive bumpers, other automotive exterior components, automobile mirror housings, an automobile grille, an automobile pillar, automobile wheel covers, automobile instrument panels and trim, automobile glove boxes, automobile door hardware and other interior trim, external automobile trim parts, such as pillars, automobile exterior lights, automobile parts within the engine compartment, an agricultural tractor or device part, a construction equipment vehicle or device part, a construction or agricultural equipment grille, a marine or personal water craft part, an all terrain vehicle or all terrain vehicle part, plumbing equipment, valves and pumps, air conditioning heating and cooling parts, furnace and heat pump parts, computer parts, electronics parts, projector parts, electronic display parts, copier parts, scanner parts, electronic printer toner cartridges, hair driers, irons, coffee makers, toasters, washing machines, microwaves, ovens, power tools, electric components, electric enclosures, lighting parts, dental instruments, medical instruments, medical or dental lighting parts, an aircraft part, a train or rail part, a seating component, sidewalls, ceiling parts, cookware, medical instrument trays, animal cages, fibers, laser welded medical devices, fiber optics, lenses (auto and non-auto), cell phone parts, greenhouse components, sun room components, fire helmets, safety shields, safety glasses, gas pump parts, hand held electronic device enclosures or parts (e.g. walkie-talkie, scanner, media/MP3/MP4 player, radio, GPS system, ebook, tablet), wearable electronic devices (e.g. smart watch, training/tracking device, activity/sleep monitoring system, wristband, or glasses), hand held tool enclosures or parts, smart phone enclosures or parts, and turbine blades.

In certain embodiments, the article is one that requires or must include a material having a UL94 5VA rating performance. Articles that require a UL94 5VA rating include, but are not limited to, computer housings, computer housings and business machine housings and parts such as housings and parts for monitors, computer routers, copiers, desk top printers, large office/industrial printers, handheld electronic device housings such as computer or business machine housings, housings for hand-held devices, components for light fixtures including LED fixtures or home or office appliances, humidifier housings, thermostat control housings, air conditioner drain pans, outdoor cabinets, telecom enclosures and infrastructure, Simple Network Intrusion Detection System (SNIDS) devices, network interface devices, smoke detectors, components and devices in plenum spaces, components for medical applications or devices such as medical scanners, X-ray equipment, and ultrasound devices, electrical boxes and enclosures, and electrical connectors.

In certain embodiments, the article is one that requires hydrothermal stability, such as a wind turbine blade, a steam sterilizable medical device, a food service tray, utensiles and equipment.

In certain embodiments, the article is one that requires a combination of transparency, flame resistance, and/or impact resistance. For example, in certain embodiments the article may be a safety shield, safety goggles, a gas/fuel pump housing, a display window or part, or the like.

Photo Patterning

Photoresist and other photopolymers can use patterned masks to build complex structures on flat surfaces by reacting only specified regions of polymer that are exposed though the patterned mask. This concept can be used with the cross-linkable polycarbonate resins of the present disclosure to enhance the properties of polycarbonate articles incorporating such resins. Selective exposure to UV light causes crosslinking in specific portions/locations of the article, which increases the molecular weight of the polycarbonate resin in the exposed region. This allows control of molecular weight where it is needed, and also limits the amount of cross-linking in areas/locations that do not need cross-linking. Cosmetic/aesthetic effects can thus be avoided in the non-exposed regions. Exposure to UV light can also change the refractive index of the polycarbonate resin in the exposed region. The selective blocking of UV light can be used to create photopatterns on the surface of the polycarbonate article that depend on the structure and design of the photomask.

It is also noted that UV light, e.g. >320 nm in wavelength, passes through polycarbonate materials. Thus, polycarbonates may be a good substrate to use when glass is not advantageous.

It is contemplated that in some applications, a photomask is used to shield some portions of the polycarbonate article and to expose other portions of the article to UV light. The photomask is a substrate that blocks some light while selectively permitting other light to pass though via patterned openings. The photomask is placed upon a surface of the polycarbonate article, and UV light is then shined on the photomask opposite the polycarbonate article. The regions of the article that are exposed to UV light will crosslink, and the regions of the article that are blocked will remain unreacted. The resulting article has a surface that is partially cross-linked and partially non-cross-linked.

By selectively applying light to a photomask, one could envision patterning effects and selective location of UV curing in regions whenever it is needed. For instance, there may be portions of a molded article which see more abusive conditions than in the remaining sections. A higher UV dose in that region would improve resistance there while preventing excessive UV exposure on the rest of the article.

In other applications, it is contemplated that portions of the polycarbonate article could be selectively exposed by focusing an ultraviolet light source at the desired portions. Rather than a diffuse light source, for example, a narrow-beam UV light source such as a laser could be used.

The UV light can come from any source of UV light such as mercury vapor, High-Intensity Discharge (HID), or various UV lamps. The exposure time can range from a few minutes to several days. Examples of UV-emitting light bulbs include mercury bulbs (H bulbs), or metal halide doped mercury bulbs (D bulbs, H+ bulbs, and V bulbs). Other combinations of metal halides to create a UV light source are also contemplated. A mercury arc lamp is not used for irradiation. An H bulb has strong output in the range of 200 nm to 320 nm. The D bulb has strong output in the 320 nm to 400 nm range. The V bulb has strong output in the 400 nm to 420 nm range. It may also be advantageous to use a UV light source where the harmful wavelengths are removed or not present, using filters.

It may also be advantageous to use a UV light source where the harmful wavelengths (those that cause polymer degradation or excessive yellowing) are removed or not present. Equipment suppliers such as Heraeus Noblelight and Fusion UV provide lamps with various spectral distributions. The light can also be filtered to remove harmful or unwanted wavelengths of light. This can be done with optical filters that are used to selectively transmit or reject a wavelength or range of wavelengths. These filters are commercially available from a variety of companies such as Edmund Optics or Praezisions Glas & Optik GmbH. Bandpass filters are designed to transmit a portion of the spectrum, while rejecting all other wavelengths. Longpass edge filters are designed to transmit wavelengths greater than the cut-on wavelength of the filter. Shortpass edge filters are used to transmit wavelengths shorter than the cut-off wavelength of the filter. Various types of materials, such as borosilicate glass, can be used as a long pass filter. Schott and/or Praezisions Glas & Optik GmbH for example have the following long pass filters: WG225, WG280, WG295, WG305, WG320 which have cut-on wavelengths of ˜225, 280, 295, 305, and 320 nm, respectively. These filters can be used to screen out the harmful short wavelengths while transmitting the appropriate wavelengths for the crosslinking reaction.

An exemplary UV light source is a collimated UV light source, which aligns the UV rays. If high resolution crosslinking is not necessary, a fixed light source can provide sufficient discrimination.

In particular embodiments, the article/photomask is exposed to a selected UV light range having wavelengths from about 280 nanometers (nm) to about 380 nm, or from about 330 nm to about 380 nm, or from about 280 nm to about 360 nm, or from about 330 nm to about 360 nm. The wavelengths in a “selected” light range have an internal transmittance of greater than 50%, with wavelengths outside of the range having an internal transmittance of less than 50%. The change in transmittance may occur over a range of 20 nm. Reference to a selected light range should not be construed as saying that all wavelengths within the range transmit at 100%, or that all wavelengths outside the range transmit at 0%.

In some embodiments, the UV radiation is filtered to provide an effective dosage of at least 2 J/cm² of UVA radiation and no detectable UVC radiation, as measured using an EIT UV PowerPuck™ II. In other more specific embodiments, the UV radiation is filtered to provide an effective dosage of at least 3 J/cm² of UVA radiation and no detectable UVC radiation, or at least 12 J/cm² of UVA radiation and no detectable UVC radiation, or at least 21 J/cm² of UVA radiation and no detectable UVC radiation, or at least 36 J/cm² of UVA radiation and no detectable UVC radiation, as measured using an EIT UV PowerPuck™ II.

In certain embodiments, the article/photomask is exposed to a dosage of about 21 J/cm² to about 60 J/cm² of UVA radiation, or in more particular embodiments a dosage of about 6 J/cm² to about 36 J/cm² of UVA radiation.

The following examples are provided to illustrate the polymeric compositions/blends, products, processes and properties of the present disclosure. The examples are merely illustrative and are not intended to limit the disclosure to the materials, conditions, or process parameters set forth therein.

### EXAMPLES

In regions where the light was not blocked, the crosslinking reaction would increase the density of the crosslinkable polymer since the length of a newly created covalent crosslink will be smaller than the van der Waals separation distance. An increased density would increase refractive index as predicted by the Lorentz-Lorenz equation.

### Example 1: Water Contact Angle

Plaques having a thickness of 1.5 mm were molded from a copolymer made with 10 mole % DHBP, remainder bisphenol-A, and 4.0 mole % 4-hydroxybenzophenone endcaps, and having an Mw of about 22,000 g/mol according to polycarbonate standards. Each plaque was considered to be flat and uniform, but contained built in stresses from molding.

The water contact angle was measured on plaques made using a Dataphysics Contact Angle System OCA with deionized water. Measurements were taken on plaques exposed to 0 J/cm², 6 J/cm², 21 J/cm², 36 J/cm², or 60 J/cm² of UVA energy. Samples were exposed to filtered UV light provided by a Loctite Zeta 7411-S system, which used a 400 W metal halide arc lamp and behaved like a D-bulb electrodeless bulb in spectral output with a 280-nm cut-on wavelength filter. This was done because in prior experiments, filtered light showed a lower change in YI for equivalent doses of UVA compared to unfiltered UV light. Water contact angles reported in Table A are an average of three sample measurements.

TABLE A

| Sample | Dose (J/cm² UVA) | Water Contact Angle (°) |
|---|---|---|
| Example 1A | 0 | 83 |
| Example 1B | 6 | 78 |
| Example 1C | 21 | 76 |
| Example 1D | 36 | 78 |
| Example 1E | 60 | 77 |

As seen from these results, the water contact angle decreased upon the initial exposure of UVA radiation and did not significantly increase with further irradiation. Since water contact angle is largely a surface phenomenon, this change in water contact angle does not require additional dose to infiltrate into the depths of the sample. The change in water contact angle also indicated which regions were exposed to UV light and which regions were not exposed to UV light.

### Example 2: Comparison of 4-HBP with 4,4′-DHBP

Plaques were made from two compositions. One composition, labeled HBP, was a bisphenol-A homopolycarbonate containing 4.0 mole % of endcaps derived from 4-hydroxybenzophenone. The other composition, labeled DHBP, was a copolymer of 10 mole % DHBP and remainder bisphenol-A.

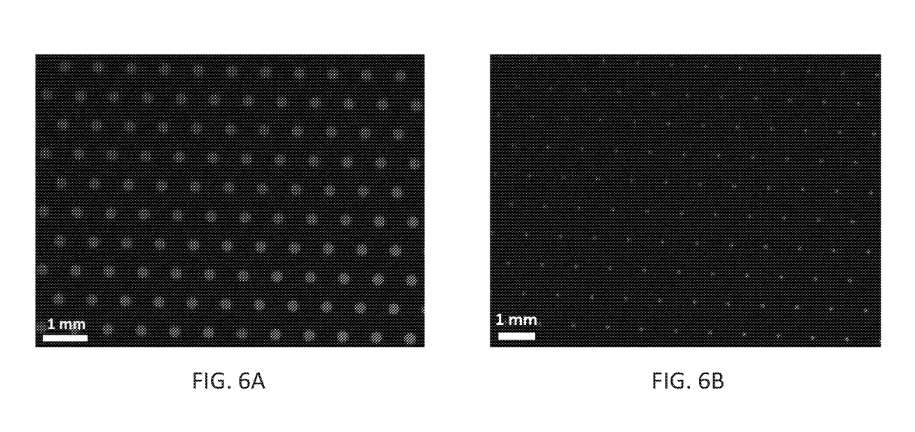

Two different replication masks were used with hexagonally patterned openings. These masks were used for a photopattern study. FIG. 6A shows one replication mask, wherein the openings are 0.25 mm (i.e. 250 μm) in diameter, with 750 μm spacing between hole center points, and arranged in a hexagonal pattern. FIG. 6B shows the other mask, therein the openings are 75 μm in diameter, with 930 μm spacing between hole center points, and arranged in a hexagonal pattern. The openings are the regions where UV light can penetrate, and the black areas are regions where UV light does not penetrate.

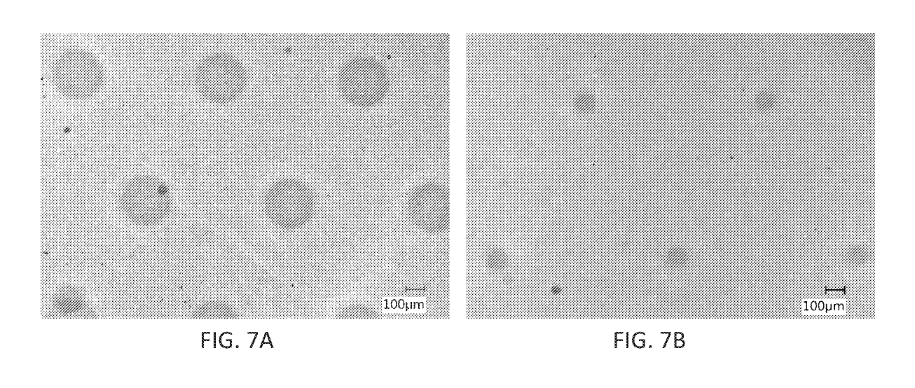

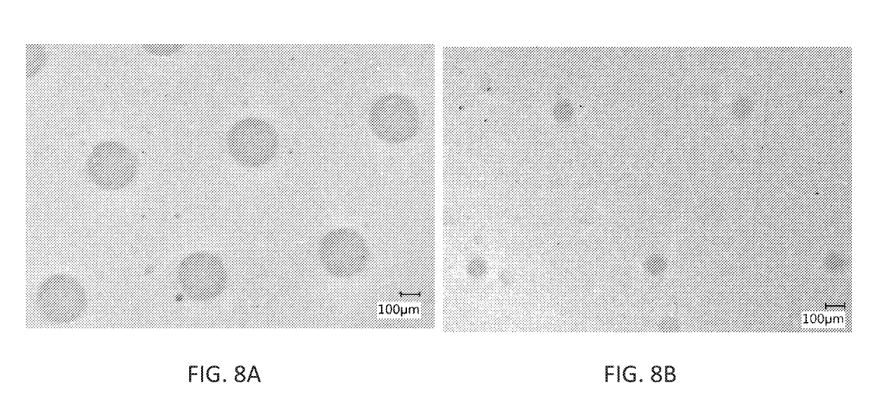

FIG. 7A is a photograph of the HBP plaque exposed to the photomask of FIG. 6A. FIG. 7B is a photograph of the HBP plaque exposed to the photomask of FIG. 6B. FIG. 8A is a photograph of the DHBP plaque exposed to the photomask of FIG. 6A. FIG. 8B is a photograph of the DHBP plaque exposed to the photomask of FIG. 6B. The circular patterns of the photomasks are visible in the exposed plaques.

Next, the refractive index for the HBP and DHBP plaques was measured using a Metricon PC-2010 prism wave-guide coupler at the same position and orientation. Refractive index was measured at 633 nm on three samples and averaged. The results are provided in Table B.

TABLE B

| UVA Dose | DHBP | HBP |
|---|---|---|
| (J/cm² UVA) | Refractive Index | Refractive Index |
| 0 | 1.5867 | 1.5829 |
| 21 | 1.5874 | 1.5838 |
| 36 | 1.5884 | 1.5842 |

Overall, there is a small but consistent increase in the refractive index after UV exposure. A change in refractive index between exposed and unexposed polymer causes light diffraction patterns. These effects would explain the color shifting seen in FIG. 7A and FIG. 7B. In regions where the polymer was exposed, the crosslinking reaction would increase the density of the crosslinkable polymer since the length of a newly created covalent crosslink will be smaller than the van der Waals separation distance. An increased density would increase refractive index as predicted by the Lorentz-Lorenz equation.

Set forth below are some embodiments of the methods and articles disclosed herein.

### Embodiment 1

A method of photopatterning a polycarbonate article formed from a polymeric composition comprising a cross-linkable polycarbonate resin containing a photoactive group derived from a benzophenone, comprising: selectively exposing a portion of the article to an effective dosage of ultraviolet radiation to cause cross-linking of the polycarbonate resin in the portion of the article to create a pattern.

### Embodiment 2

The method of Embodiment 1, wherein the portion of the article is selectively exposed by using a photomask to shield other portions of the article from exposure to the ultraviolet radiation.

### Embodiment 3

The method of Embodiment 2, wherein the portion of the article is selectively exposed by a photomask pattern having a smallest resolution from 0.075 mm to 10.0 mm to form a cross-linked portion.

### Embodiment 4

The method of any one of Embodiments 1-3, wherein the portion of the article is selectively exposed by focusing an ultraviolet light source at the selectively exposed portion.

### Embodiment 5

The method of any one of Embodiments 1-4, wherein the selectively exposed portion of the article is a potential failure point, a knit line, or an edge.

### Embodiment 6

The method of any one of Embodiments 1-5, wherein the effective dosage is from about 6 J/cm² to about 36 J/cm² of UVA radiation.

### Embodiment 7

The method of any one of Embodiments 1-6, wherein the ultraviolet radiation has a wavelength between 280 nm and 380 nm.

### Embodiment 8

The method of any one of Embodiments 1-7, wherein the ultraviolet radiation is provided by a collimated UV light source.

### Embodiment 9

The method of any one of Embodiments 1-8, wherein the benzophenone from which the photoactive group is derived is a monohydroxybenzophenone.

### Embodiment 10

The method of Embodiment 9, wherein the cross-linkable polycarbonate resin is formed from a reaction of: the monohydroxybenzophenone; a diol chain extender; and a first linker moiety comprising a plurality of linking groups, wherein each linking group can react with the hydroxyl groups of the monohydroxybenzophenone and the diol chain extender.

### Embodiment 11

The method of Embodiment 9, wherein the cross-linkable polycarbonate resin contains from about 0.5 mole % to about 5 mole % of endcap groups derived from the monohydroxybenzophenone.

### Embodiment 12

The method of any one of Embodiments 1-8, wherein the benzophenone from which the photoactive group is derived is a dihydroxybenzophenone.

### Embodiment 13

The method of Embodiment 12, wherein the cross-linkable polycarbonate resin is formed from a reaction of: the dihydroxybenzophenone; a diol chain extender; a first linker moiety comprising a plurality of linking groups, wherein each linking group can react with the hydroxyl groups of the dihydroxybenzophenone and the diol chain extender; and an endcapping agent.

### Embodiment 14

The method of Embodiment 13, wherein the dihydroxybenzophenone is 4,4′-dihydroxybenzophenone; the diol chain extender is bisphenol-A; and the first linker moiety is phosgene.

### Embodiment 15

The method of any one of Embodiments 13-14, wherein the end-capping agent is selected from the group consisting of phenol, p-t-butylphenol, p-cumylphenol, octylphenol, p-cyanophenol, and 4-hydroxybenzophenone.

### Embodiment 16

The method of any one of Embodiments 12-15, wherein the cross-linkable polycarbonate resin contains from about 0.5 mole % to about 50 mole % of repeating units derived from the dihydroxybenzophenone.

### Embodiment 17

The method of any one of Embodiments 1-16, wherein the polymeric composition further comprises a polymeric base resin.

### Embodiment 18

The method of Embodiment 17, wherein the weight ratio of the cross-linkable polycarbonate resin to the polymeric base resin is from about 50:50 to about 85:15.

### Embodiment 19

The polycarbonate article formed by the method of any one of Embodiments 1-18.

### Embodiment 20

The polycarbonate article of Embodiment 19, wherein the article is a molded article, a film, a sheet, a layer of a multilayer film, or a layer of a multilayer sheet, an automotive bumper, an automotive exterior component, an automobile mirror housing, an automobile grille, an automobile pillar, an automobile wheel cover, an automobile instrument panel or trim, an automobile glove box, an automobile door hardware or other interior trim, an automobile exterior light, an automobile part within the engine compartment, an agricultural tractor or device part, a construction equipment vehicle or device part, a construction or agricultural equipment grille, a marine or personal water craft part, an all terrain vehicle or all terrain vehicle part, plumbing equipment, a valve or pump, an air conditioning heating or cooling part, a furnace or heat pump part, a computer part, a computer router, a desk top printer, a large office/industrial printer, an electronics part, a projector part, an electronic display part, a copier part, a scanner part, an electronic printer toner cartridge, a hair drier, an iron, a coffee maker, a toaster, a washing machine or washing machine part, a microwave, an oven, a power tool, an electric component, an electric enclosure, a lighting part, a dental instrument, a medical instrument, a medical or dental lighting part, an aircraft part, a train or rail part, a seating component, a sidewall, a ceiling part, cookware, a medical instrument tray, an animal cage, fibers, a laser welded medical device, fiber optics, a lense (auto and non-auto), a cell phone part, a greenhouse component, a sun room component, a fire helmet, a safety shield, safety glasses, a gas pump part, a humidifier housing, a thermostat control housing, an air conditioner drain pan, an outdoor cabinet, a telecom enclosure or infrastructure, a Simple Network Detection System (SNIDS) device, a network interface device, a smoke detector, a component or device in a plenum space, a medical scanner, X-ray equipment, a construction or agricultural equipment, a hand held electronic device enclosure or part, a walkie-talkie enclosure or part, a scanner enclosure or part, a media/MP3/MP4 player enclosure or part, a radio enclosure or part, a GPS system enclosure or part, an ebook enclosure or part, a tablet enclosure or part, a wearable electronic device, a smart watch, a wearable training/tracking device, a wearable activity/sleep monitoring system, a wearable electronic wristband, electronic glasses, a hand held tool enclosure or part, a smart phone enclosure or part, or a turbine blade.

The present disclosure has been described with reference to exemplary embodiments. Obviously, modifications and alterations will occur to others upon reading and understanding the preceding detailed description. It is intended that the present disclosure be construed as including all such modifications and alterations insofar as they come within the scope of the appended claims or the equivalents thereof.

1. A method of photopatterning a polycarbonate article formed from a polymeric composition comprising a cross-linkable polycarbonate resin containing a photoactive group derived from a benzophenone, comprising:
selectively exposing a portion of the article to an effective dosage of ultraviolet radiation to cause cross-linking of the polycarbonate resin in the portion of the article to create a pattern.

2. The method of claim 1, wherein the portion of the article is selectively exposed by using a photomask to shield other portions of the article from exposure to the ultraviolet radiation.

3. The method of claim 2, wherein the portion of the article is vselectively exposed by a photomask pattern having a smallest resolution from 0.075 mm to 10.0 mm to form a cross-linked portion.

4. The method of claim 3, wherein the portion of the article is selectively exposed by focusing an ultraviolet light source at the selectively exposed portion.

5. The method of claim 1, wherein the selectively exposed portion of the article is a potential failure point, a knit line, or an edge.

6. The method of claim 1, wherein the effective dosage is from about 6 J/cm² to about 36 J/cm² of UVA radiation.

7. The method of claim 1, wherein the ultraviolet radiation has a wavelength between 280 nm and 380 nm.

8. The method of claim 1, wherein the ultraviolet radiation is provided by a collimated UV light source.

9. The method of claim 1, wherein the benzophenone from which the photoactive group is derived is a monohydroxybenzophenone.

10. The method of claim 9, wherein the cross-linkable polycarbonate resin is formed from a reaction of:
the monohydroxybenzophenone;
a diol chain extender; and
a first linker moiety comprising a plurality of linking groups,
wherein each linking group can react with the hydroxyl groups of the monohydroxybenzophenone and the diol chain extender.

11. The method of claim 9, wherein the cross-linkable polycarbonate resin contains from about 0.5 mole % to about 5 mole % of endcap groups derived from the monohydroxybenzophenone.

12. The method of claim 1, wherein the benzophenone from which the photoactive group is derived is a dihydroxybenzophenone

13. The method of claim 12, wherein the cross-linkable polycarbonate resin is formed from a reaction of:
the dihydroxybenzophenone;
a diol chain extender;
a first linker moiety comprising a plurality of linking groups, wherein each linking group can react with the hydroxyl groups of the dihydroxybenzophenone and the diol chain extender; and
an endcapping agent.

14. The method of claim 13, wherein the dihydroxybenzophenone is 4,4′-dihydroxybenzophenone; the diol chain extender is bisphenol-A; and the first linker moiety is phosgene.

15. The method of claim 13, wherein the end-capping agent is selected from the group consisting of phenol, p-t-butylphenol, p-cumylphenol, octylphenol, p-cyanophenol, and 4-hydroxybenzophenone.

16. The method of claim 13, wherein the cross-linkable polycarbonate resin contains from about 0.5 mole % to about 50 mole % of repeating units derived from the dihydroxybenzophenone.

17. The method of claim 1, wherein the polymeric composition further comprises a polymeric base resin.

18. The method of claim 17, wherein the weight ratio of the cross-linkable polycarbonate resin to the polymeric base resin is from about 50:50 to about 85:15.

19. The polycarbonate article formed by the method of claim 1.

20. The polycarbonate article of claim 19, wherein the article is a molded article, a film, a sheet, a layer of a multilayer film, or a layer of a multilayer sheet, an automotive bumper, an automotive exterior component, an automobile mirror housing, an automobile grille, an automobile pillar, an automobile wheel cover, an automobile instrument panel or trim, an automobile glove box, an automobile door hardware or other interior trim, an automobile exterior light, an automobile part within the engine compartment, an agricultural tractor or device part, a construction equipment vehicle or device part, a construction or agricultural equipment grille, a marine or personal water craft part, an all terrain vehicle or all terrain vehicle part, plumbing equipment, a valve or pump, an air conditioning heating or cooling part, a furnace or heat pump part, a computer part, a computer router, a desk top printer, a large office/industrial printer, an electronics part, a projector part, an electronic display part, a copier part, a scanner part, an electronic printer toner cartridge, a hair drier, an iron, a coffee maker, a toaster, a washing machine or washing machine part, a microwave, an oven, a power tool, an electric component, an electric enclosure, a lighting part, a dental instrument, a medical instrument, a medical or dental lighting part, an aircraft part, a train or rail part, a seating component, a sidewall, a ceiling part, cookware, a medical instrument tray, an animal cage, fibers, a laser welded medical device, fiber optics, a lense (auto and non-auto), a cell phone part, a greenhouse component, a sun room component, a fire helmet, a safety shield, safety glasses, a gas pump part, a humidifier housing, a thermostat control housing, an air conditioner drain pan, an outdoor cabinet, a telecom enclosure or infrastructure, a Simple Network Detection System (SNIDS) device, a network interface device, a smoke detector, a component or device in a plenum space, a medical scanner, X-ray equipment, a construction or agricultural equipment, a hand held electronic device enclosure or part, a walkie-talkie enclosure or part, a scanner enclosure or part, a media/MP3/MP4 player enclosure or part, a radio enclosure or part, a GPS system enclosure or part, an ebook enclosure or part, a tablet enclosure or part, a wearable electronic device, a smart watch, a wearable training/tracking device, a wearable activity/sleep monitoring system, a wearable electronic wristband, electronic glasses, a hand held tool enclosure or part, a smart phone enclosure or part, or a turbine blade.
